(19) United States
(12) Patent Application Publication
(10) Pub. No.: US 2026/0129776 A1
(43) Pub. Date: May 7, 2026

(54) ELECTRONIC DEVICE HAVING FLEXIBLE DISPLAY

(71) Applicant: Samsung Electronics Co., Ltd., Suwon-si (KR)

(72) Inventors: Hyunmoon CHO, Suwon-si (KR); Jinhyun PARK, Suwon-si (KR); Seungtaek OH, Suwon-si (KR); Sunghwan LIM, Suwon-si (KR)

(21) Appl. No.: 19/435,379

(22) Filed: Dec. 29, 2025

Related U.S. Application Data
(63) Continuation of application No. PCT/KR2024/006915, filed on May 22, 2024.

(30) Foreign Application Priority Data
Jun. 30, 2023 (KR) 10-2023-0085232
Jul. 31, 2023 (KR) 10-2023-0099497

(51) Int. Cl. H05K 5/02

(52) U.S. Cl. CPC H05K 5/0226

(57) ABSTRACT

An electronic device may include: a first housing; a second housing that is foldably connected to the first housing through a hinge module; and a flexible display supported by, directly or indirectly, the first housing and the second housing, wherein the flexible display includes: a glass layer having a first surface and a second surface opposite to the first surface, and including a plurality of first patterns recessed from the first surface and a plurality of second patterns recessed from the second surface; a first filling member filled in the plurality of first patterns; and a second filling member filled in the plurality of second patterns and having a hardness lower than a hardness of the first filling member.

### CROSS-REFERENCE TO RELATED APPLICATIONS

This application is a continuation of International Application No. PCT/KR2024/006915 designating the United States, filed on May 22, 2024, in the Korean Intellectual Property Receiving Office and claiming priority to Korean Patent Application Nos. 10-2023-0085232, filed on Jun. 30, 2023, and 10-2023-0099497, filed on Jul. 31, 2023, in the Korean Intellectual Property Office, the disclosures of each of which are incorporated by reference herein in their entireties.

### TECHNICAL FIELD

Various example embodiments may relate to an electronic device having a flexible display.

### BACKGROUND

With the development of electronic, information, and communication technologies, a variety of functions are being integrated into a single portable communication device or electronic device. For example, a smartphone includes the functions of a sound player, an imaging device, or an organizer, in addition to communication functions. Furthermore, a wider range of functions can be implemented on a smartphone by installing additional applications.

As smartphones or other personal/portable communication devices spread, users' demand for portability and use convenience is on the rise. For example, a touchscreen display may not only serve as an output device of visual information but also provide a virtual keyboard that replaces a mechanical input device (e.g., a button input device). As such, portable communication devices or electronic devices may be made compact while delivering further enhanced applicability (e.g., a larger screen). Furthermore, with the commercialization of flexible displays, such as foldable or rollable displays, electronic devices are expected to offer even greater portability and convenience.

### SUMMARY

Various example embodiments may provide a flexible display having a plurality of patterns provided in a bending area, wherein the plurality of patterns may be filled with filling members having different hardnesses.

An electronic device according to an example embodiment may include a first housing. The electronic device may include a second housing foldably connected, directly or indirectly, to the first housing through a hinge module. The electronic device may include a flexible display supported by, directly or indirectly, the first housing and the second housing. The flexible display may include a glass layer having a first surface and a second surface opposite to the first surface, and including a plurality of first patterns recessed from the first surface and a plurality of second patterns recessed from the second surface. The flexible display may include a first filling member filling the plurality of first patterns. The flexible display may include a second filling member filling the plurality of second patterns and having a lower hardness than the first filling member.

Various example embodiments may reduce a difference in touch feeling between the glass layer and the filling member by filling, with a first filling member having substantially the same hardness as the glass layer, the plurality of first patterns exposed to the outside in a glass layer having a plurality of patterns formed in an area corresponding to a bending area of the flexible display.

Further, flexibility of the flexible display may be enhanced by filling, with a second filling member having a lower hardness than the first filling member, a plurality of second patterns opposite to the plurality of first patterns.

Effects of the present invention are not limited to the foregoing, and other unmentioned effects would be apparent to one of ordinary skill in the art from the following description. In other words, unintended effects in practicing example embodiments may also be derived by one of ordinary skill in the art from example example embodiments.

### BRIEF DESCRIPTION OF DRAWINGS

In connection with the description of the drawings, the same or similar reference numerals may be used to denote the same or similar elements.

FIG. 1 is a view illustrating an electronic device in a network environment according to various example embodiments.

FIG. 2A is a perspective view illustrating an electronic device in a flat state or unfolded state according to an example embodiment.

FIG. 2B is a plan view illustrating a front surface of an electronic device in an unfolded state according to an example embodiment.

FIG. 2C is a plan view illustrating a rear surface of an electronic device in an unfolded state according to an example embodiment.

FIG. 3A is a perspective view illustrating an electronic device in a folded state according to an example embodiment.

FIG. 3B is a perspective view illustrating an electronic device in an intermediate state according to an example embodiment.

FIG. 4 is an exploded perspective view illustrating an electronic device according to an example embodiment.

FIG. 5 is an exploded perspective view illustrating a flexible display according to various example embodiments.

FIG. 6 is a plan view illustrating a window layer according to various example embodiments.

FIG. 7 is a cross-sectional view taken along line I-I′ of FIG. 6;

FIG. 8 is an enlarged view illustrating portion A illustrated in FIG. 6.

FIG. 9 is a graph illustrating strength simulation results by thickness of a glass layer according to an example embodiment.

FIG. 10 is a graph illustrating pen pressure simulation results by thickness of a first filling member according to an example embodiment.

FIG. 11 is a manufacturing process diagram illustrating a window layer according to an example embodiment.

FIG. 12 is a view illustrating a process of forming a plurality of patterns in a glass layer according to an example embodiment.

FIG. 13 is a view illustrating a process of filling a plurality of patterns with a filling member according to an example embodiment.

FIG. 14 is a cross-sectional view illustrating a flexible display according to an example embodiment.

FIG. 15 is a cross-sectional view illustrating a glass layer according to an example embodiment.

FIG. 16 is a view schematically illustrating an electronic device in an unfolded state according to an example embodiment.

FIG. 17 is a view schematically illustrating the electronic device of FIG. 16 in a folded state according to an example embodiment.

FIG. 18 is a view illustrating shape and arrangement configuration of a plurality of patterns according to a bending direction of the flexible display of FIG. 16 according to an example embodiment.

FIG. 19 is a view illustrating an extended state of an electronic device according to an example embodiment.

FIG. 20 is a view illustrating a retracted state of an electronic device according to an example embodiment.

FIG. 21 is a view illustrating shape and arrangement configuration of a plurality of patterns according to bending of a flexible display in a bendable area according to an example embodiment.

### DETAILED DESCRIPTION

It should be appreciated that various embodiments of the present disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements.

It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases.

As used herein, such terms as “1st” and “2nd,” or “first” and “second” may be used to simply distinguish a corresponding component from another, and does not limit the components in other aspect (e.g., importance or order).

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof.

It will be understood that when a component is referred to as “connected to,” “coupled to”, “supported on,” or “contacting” another component, the components may be connected to, coupled to, supported on, or contact each other directly or via a third component.

Throughout the specification, when one component is positioned “on” another component, the first component may be positioned directly on the second component, or other component(s) may be positioned between the first and second component.

The term “and/or” may denote a combination(s) of a plurality of related components as listed or any of the components.

Hereinafter, the working principle and embodiments of the present invention are described with reference to the accompanying drawings.

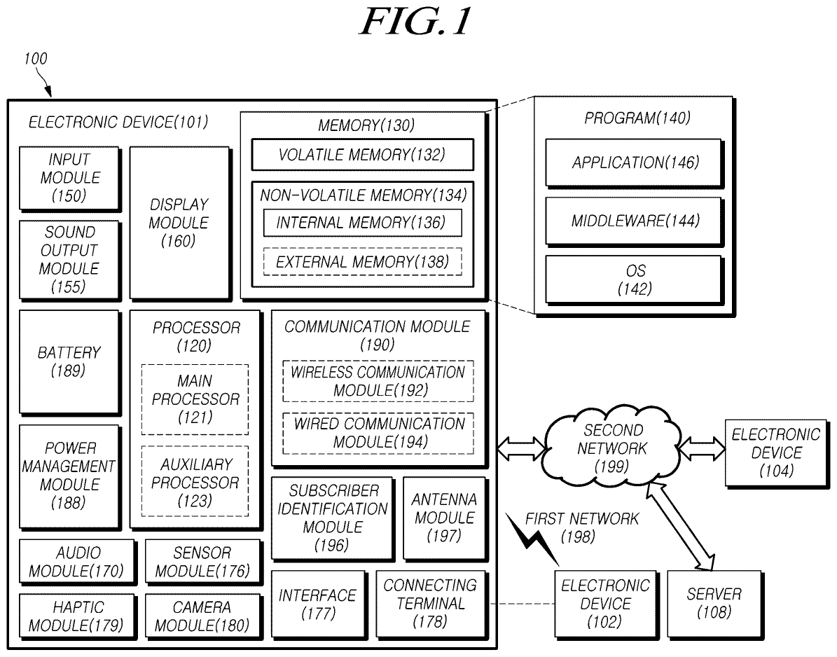

FIG. 1 is a block diagram illustrating an electronic device 101 in a network environment 100 according to various embodiments.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., the program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123.

According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operation state (e.g., power or temperature) of the electronic device 101 or an external environmental state (e.g., the user's state), and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected, directly or indirectly, with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mm Wave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mm Wave antenna module may include a printed circuit board, a RFIC disposed on, directly or indirectly, a first surface (e.g., the bottom surface) of the printed circuit board, or adjacent to the first surface and capable of supporting a designated high-frequency band (e.g., the mmWave band), and a plurality of antennas (e.g., array antennas) disposed on, directly or indirectly, a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various example embodiments may be one of various types of electronic devices. The electronic devices may include, for example, a portable communication device (e.g., a smartphone), a computer device, a portable multimedia device, a portable medical device, a camera, a wearable device, or a home appliance. According to an example embodiment, the electronic devices are not limited to those described above.

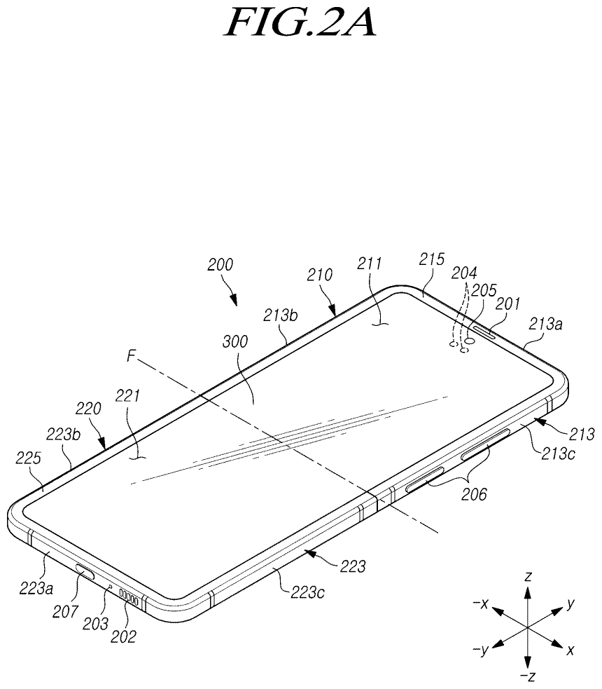

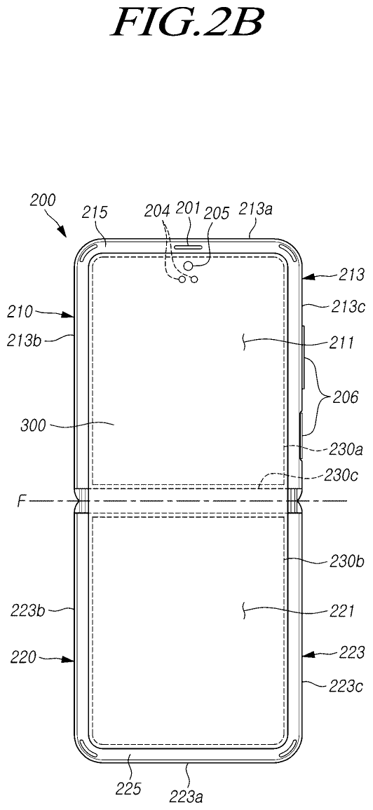

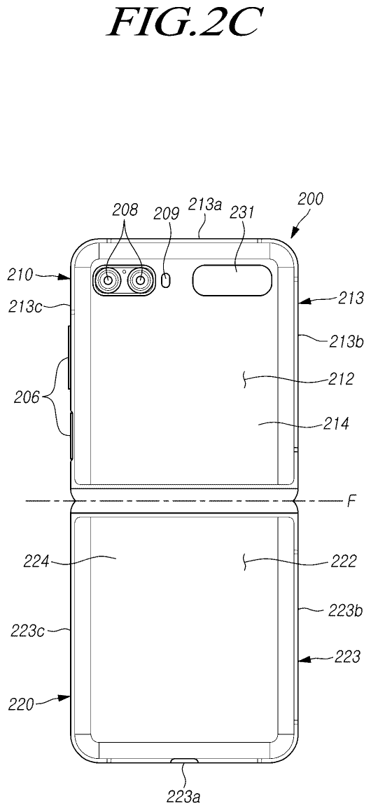

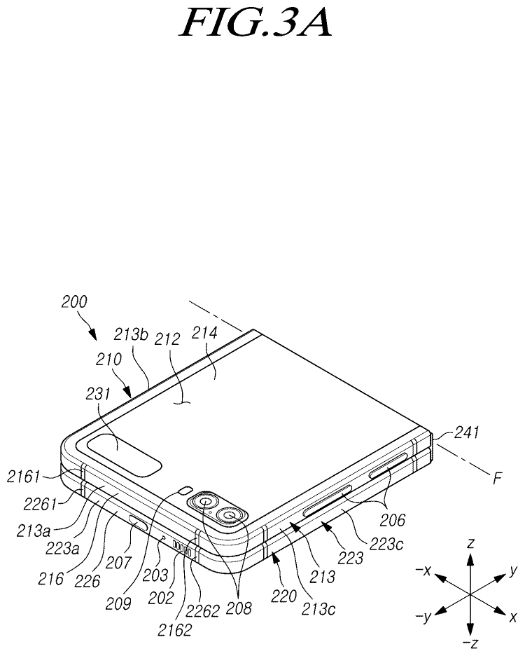

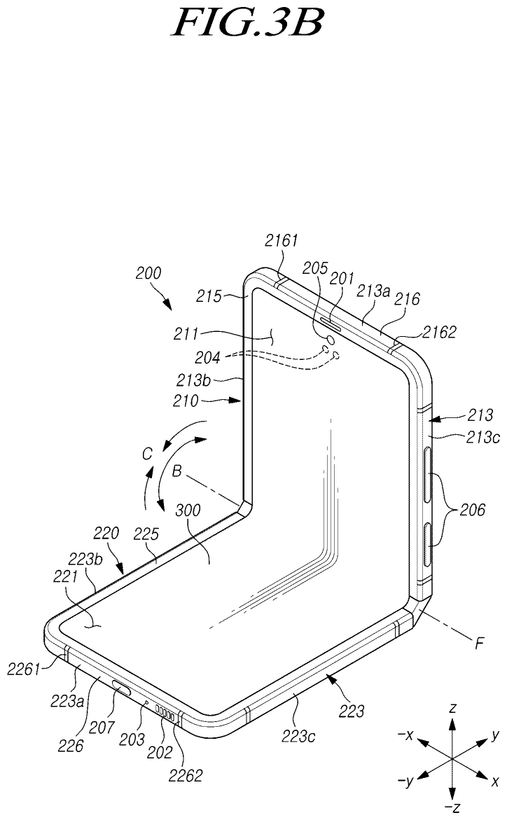

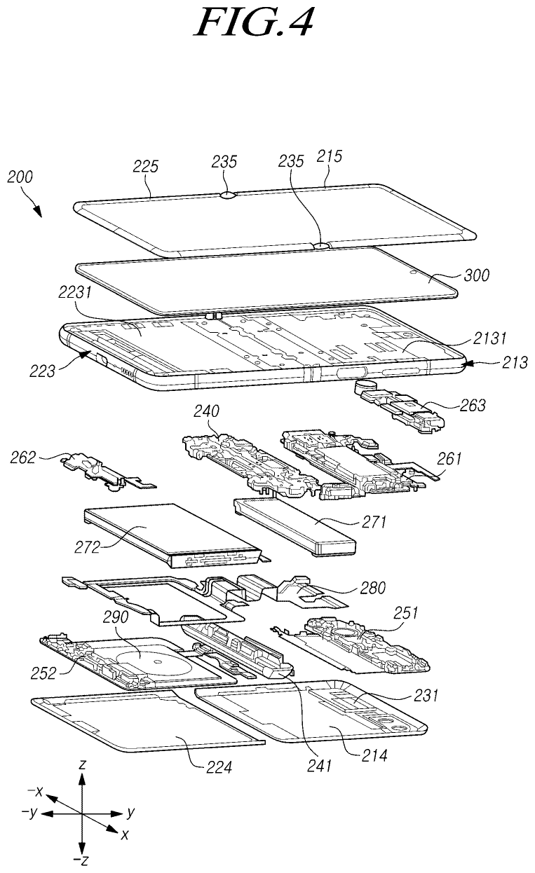

FIG. 2A is a perspective view illustrating an electronic device in a flat state or unfolded state according to an example embodiment. FIG. 2B is a plan view illustrating a front surface of an electronic device in an unfolded state according to an example embodiment. FIG. 2C is a plan view illustrating a rear surface of an electronic device in an unfolded state according to an example embodiment. FIG. 3A is a perspective view illustrating an electronic device in a folded state according to an example embodiment. FIG. 3B is a perspective view illustrating an electronic device in an intermediate state according to an example embodiment. FIG. 4 is an exploded perspective view illustrating an electronic device according to an example embodiment.

Referring to FIGS. 2A to 4, an electronic device 200 may include a pair of housings 210 and 220 (e.g., a foldable housing) rotatably coupled to be folded about a hinge module 240 while facing each other. According to an embodiment, the electronic device 200 may include a flexible display 300 (e.g., the display 160 of FIG. 1) disposed in an area formed by the pair of housings 210 and 220. According to an embodiment, the first housing 210 and the second housing 220 may be disposed on two opposite sides of the folding axis (axis F) and be substantially symmetrical in shape with respect to the folding axis (e.g., axis F). According to an embodiment, the first housing 210 and the second housing 220 may form different angles or distances depending on whether the foldable electronic device 200 is in an unfolded state (or flat state), a folded state, or an intermediate state.

The pair of housings 210 and 220 may include a first housing 210 (e.g., a first housing structure) coupled to the hinge module 240 and a second housing 220 (e.g., a second housing structure) coupled to the hinge module 240. According to an embodiment, the first housing 210 may include a first surface 211 facing in a first direction (e.g., front direction) (z-axis direction) and a second surface 212 facing in a second direction (e.g., rear direction) (−z-axis direction) opposite to the first surface 211, in the unfolded state.

According to an embodiment, the second housing 220 may include a third surface 221 facing in the first direction (z-axis direction) and a fourth surface 222 facing in the second direction (−z-axis direction), in the unfolded state. According to an embodiment, the electronic device 200 may be operated in such a manner where in the unfolded state, the first surface 211 of the first housing 210 and the third surface 221 of the second housing 220 face in substantially the same first direction (z-axis direction) and, in the folded state, the first surface 211 and the third surface 221 face each other.

According to an embodiment, the foldable electronic device 200 may be operated in such a manner where in the unfolded state, the second surface 212 of the first housing 210 and the fourth surface 222 of the second housing 220 face in substantially the same second direction (−z-axis direction) and, in the folded state, the second surface 212 and the fourth surface 222 face in opposite directions to each other. For example, in the folded state, the second surface 212 may face in the first direction (z-axis direction), and the fourth surface 222 may face in the second direction (−z-axis direction).

According to an embodiment, the first housing 210 may include a first side frame 213 at least partially forming the appearance of the electronic device 200 and a first rear cover 214 coupled with the first side frame 213 and forming at least a portion of the second surface 212 of the electronic device 200. According to an embodiment, the first side frame 213 may include a first side surface 213a, a second side surface 213b extending from an end of the first side surface 213a, and a third side surface 213c extending from the other end of the first side surface 213a. According to an embodiment, the first side frame 213 may be formed in a rectangular (or square) shape through the first side surface 213a, the second side surface 213b, and the third side surface 213c.

According to an embodiment, the second housing 220 may include a second side frame 223 at least partially forming the appearance of the electronic device 200 and a second rear cover 224 coupled with the second side frame 223 and forming at least a portion of the fourth surface 222 of the electronic device 200. According to an embodiment, the second side frame 223 may include a fourth side surface 223a, a fifth side surface 223b extending from an end of the fourth side surface 223a, and a sixth side surface 223c extending from the other end of the fourth side surface 223a. According to an embodiment, the second side frame 223 may be formed in a rectangular shape through the fourth side surface 223a, the fifth side surface 223b, and the sixth side surface 223c.

According to an embodiment, the pair of housings 210 and 220 is not limited to the shape and coupling shown but may rather be implemented in other shapes or via a combination and/or coupling of other components. For example, in an embodiment, the first side frame 213 may be integrally formed with the first rear cover 214, and the second side frame 223 may be integrally formed with the second rear cover 224.

According to an embodiment, in the unfolded state of the electronic device 200, the second side surface 213b of the first side frame 213 may be connected with the fifth side surface 223b of the second side frame 223 without a gap. According to an embodiment, in the unfolded state of the electronic device 200, the third side surface 213c of the first side frame 213 may be connected with the sixth side surface 223c of the second side frame 223 without a gap. According to an embodiment, in the unfolded state of the electronic device 200, the sum of the lengths of the second side surface 213b and the fifth side surface 223b may be configured to be larger than the length of the first side surface 213a and/or the fourth side surface 223a. Further, the sum of the lengths of the third side surface 213c and the sixth side surface 223c may be configured to be larger than the length of the first side surface 213a and/or the fourth side surface 223a.

According to an embodiment, the first side frame 213 and/or the second side frame 223 may be formed of metal or may further include a polymer injected into the metal. According to an embodiment, the first side frame 213 and/or the second side frame 223 may include at least one conductive portion 216 and/or 226 electrically segmented through at least one segmenter 2161, 2162, and/or 2261 or 2262 formed of a polymer. In this case, the at least one conductive portion may be electrically connected, directly or indirectly, with a wireless communication circuit included in the electronic device 200 and be thus used as an antenna operating in at least one designated band (e.g., a legacy band).

According to an embodiment, the first rear cover 214 and/or the second rear cover 224 may be formed of at least one of, or a combination of at least two of, laminated or colored glass, ceramic, polymer, or metal (e.g., aluminum, stainless steel (STS), or magnesium).

According to an embodiment, the flexible display 300 may be disposed from the first surface 211 of the first housing 210 across the hinge module 240 up to at least a portion of the third surface 221 of the second housing 220. For example, the flexible display 300 may include a first flat portion 230a substantially corresponding to the first surface 211, a second flat portion 230b corresponding to the third surface 221, and a bendable portion 230c connecting the first flat portion 230a and the second flat portion 230b and corresponding to the hinge module 240. According to an embodiment, the electronic device 200 may include a first protective cover 215 (e.g., first protective frame or first decoration member) coupled along the edge of the first housing 210. According to an embodiment, the electronic device 200 may include a second protective cover 225 (e.g., second protective frame or second decoration member) coupled along the edge of the second housing 220. According to an embodiment, the first protective cover 215 and/or the second protective cover 225 may be formed of a metal or polymer material. According to an embodiment, the first protective cover 215 and/or the second protective cover 225 may be used as a decoration member. According to an embodiment, the flexible display 300 may be positioned such that an edge of the first flat portion 230a is interposed between the first housing 210 and the first protective cover 215. According to an embodiment, the flexible display 300 may be positioned such that an edge of the second flat portion 230b is interposed between the second housing 220 and the second protective cover 225. According to an embodiment, the flexible display 300 may be positioned such that the edge of the flexible display 300 corresponding to a protective cap 235 is protected through the protective cap 235 disposed in the area corresponding to the hinge module 240. Accordingly, the edge of the flexible display 300 may be substantially protected from the outside.

According to an embodiment, the electronic device 200 may include a hinge housing 241 (e.g., hinge cover) that supports the hinge module 240 and is disposed to be exposed to the outside in the folded state of the electronic device 200 and, in the unfolded state of the electronic device 200, is drawn in a first space and a second space not to be seen from the outside.

According to an embodiment, the electronic device 200 may include a sub display 231 (e.g., a second display) disposed separately from the flexible display 300 (e.g., a first display). According to an embodiment, as the sub display 231 is disposed on, directly or indirectly, the second surface 212 of the first housing 210 to be at least partially exposed, the sub display 231 may display status information about the electronic device 200 which replaces the display function of the flexible display 300, in the folded state. According to an embodiment, the sub display 231 may be disposed to be viewed from the outside through at least a partial area of the first rear cover 214. In an embodiment, the sub display 231 may be disposed on, directly or indirectly, the fourth surface 222 of the second housing 220. In this case, the sub display 231 may be disposed to be visible from the outside through at least a partial area of the second rear cover 224.

According to an embodiment, the electronic device 200 may include at least one of an input device (e.g., a microphone), sound output devices 201 and 202, a sensor module 204, a camera device (e.g., the first camera device 205 and/or the second camera device 208), a key input device 206, or a connector port 207. In the illustrated embodiment, the input device (e.g., the microphone), sound output devices 201 and 202, the sensor module 204, the camera device (e.g., the first camera device 205 and/or the second camera device 208), the key input device 206, or the connector port 207 refer to a hole or shape formed in the first housing 210 or the second housing 220, but may be defined to include a substantial electronic component (e.g., an input device, a sound output device, a sensor module, or a camera device) disposed inside the electronic device 200 and operating through the hole or shape.

According to an embodiment, the input device may include at least one microphone 203 disposed in the second housing 220. In an embodiment, the input device may include a plurality of microphones 203 disposed to detect the direction of the sound. In an embodiment, the plurality of microphones 203 may be disposed at appropriate positions in the first housing 210 and/or the second housing 220. According to an embodiment, the sound output devices 201 and 202 may include speakers. According to an embodiment, the speakers may include a call receiver 201 disposed in the first housing 210 and a speaker 202 disposed in the second housing 220. In an embodiment, the input device, the sound output devices 201 and 202, and the connector port 207 may be disposed in a space provided in the first housing 210 and/or the second housing 220 of the electronic device 200 and may be exposed to an external environment through at least one hole formed in the first housing 210 and/or the second housing 220. According to an embodiment, the at least one connector port 207 may be used to transmit and receive power and/or data to and from an external electronic device. In an embodiment, at least one connector port (e.g., an ear jack hole) may receive a connector (e.g., an ear jack) for transmitting and receiving an audio signal to and from an external electronic device. In an embodiment, the holes formed in the first housing 210 and/or the second housing 220 may be commonly used for the input device and the sound output devices 201 and 202. In an embodiment, the sound output devices 201 and 202 may include speakers (e.g., piezo speakers) that operate without holes formed in the first housing 210 and/or the second housing 220.

According to an embodiment, the sensor module 204 may generate an electrical signal or a data value corresponding to an internal operating state of the electronic device 200 or an external environmental state. The sensor module 204 may detect, e.g., an external environment through the first surface 211 of the first housing 210. In an embodiment, the electronic device 200 may further include at least one sensor module disposed to detect an external environment through the second surface 212 of the first housing 210. According to an embodiment, the sensor module 204 (e.g., an illuminance sensor) may be disposed under the flexible display 300 to detect an external environment through the flexible display 300. According to an embodiment, the sensor module 204 may include at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, an illuminance sensor, a proximity sensor, a biometric sensor, an ultrasonic sensor, or an illuminance sensor.

According to an embodiment, a camera device (e.g., the first camera device 205 and/or the second camera device 208) may include a first camera device 205 (e.g., a front camera device) disposed on, directly or indirectly, the first surface 211 of the first housing 210 and a second camera device 208 disposed on, directly or indirectly, the second surface 212 of the first housing 210. The electronic device 200 may further include a flash 209 disposed near the second camera device 208. According to an embodiment, a camera device (e.g., the first camera device 205 and/or the second camera device 208) may include one or more lenses, an image sensor, and/or an image signal processor. The flash 209 may include, e.g., a light emitting diode or a xenon lamp. According to an embodiment, the camera device (e.g., the first camera device 205 and/or the second camera device 208) may be disposed so that two or more lenses (a wide-angle lens, an ultra-wide-angle lens, or a telephoto lens) and image sensors are positioned on one surface (e.g., the first surface 211, the second surface 212, the third surface 221, or the fourth surface 222) of the electronic device 200. In an embodiment, the camera device (e.g., the first camera device 205 and/or the second camera device 208) may include time of flight (TOF) lenses and an image sensor.

According to an embodiment, the key input device 206 (e.g., a key button) may be disposed on, directly or indirectly, the third side surface 213c of the first side frame 213 of the first housing 210. In an embodiment, the key input device 206 may be disposed on at least one of the other side surfaces 213a and 213b of the first housing 210 and/or the side surfaces 223a, 223b, and 223c of the second housing 220. In an embodiment, the electronic device 200 may not include some or all of the key input devices 206, and the key input devices 206 not included may be implemented in other forms, such as a soft key, on the flexible display 300. In an embodiment, the key input device 206 may be implemented using a pressure sensor included in the flexible display 300.

According to an embodiment, some of the camera devices (e.g., the first camera device 205 and/or the second camera device 208) or the sensor module 204 may be disposed to be exposed through the flexible display 300. For example, the first camera device 205 or the sensor module 204 may be disposed to contact an external environment through an opening (e.g., a through hole) at least partially formed in the flexible display 300 in the internal space of the electronic device 200. According to an embodiment, some sensor modules 204 may be disposed to perform their functions without being visually exposed through the flexible display 300 in the internal space of the electronic device 200. For example, in this case, the area of the flexible display 300 facing the sensor module may not need an opening.

Referring to FIG. 3B, the electronic device 200 may be operated to maintain an intermediate state through the hinge module 240. In this case, the electronic device 200 may control the flexible display 300 to display different contents in the display area corresponding to the first surface 211 and the display area corresponding to the third surface 221. According to an embodiment, the electronic device 200 may operate in a substantially unfolded state (e.g., the unfolded state of FIG. 2A) and/or a substantially folded state (e.g., the folded state of FIG. 3A) based on a predetermined inflection angle (e.g., the angle between the first housing 210 and the second housing 220 in the intermediate state) through the hinge module 240. For example, in case that a pressing force is provided in the unfolding direction (direction B) in the unfolded state at a predetermined inflection angle through the hinge module 240, the electronic device 200 may be operated to transition to the unfolded state (e.g., the unfolded state of FIG. 2A). For example, the electronic device 200 may be operated through the hinge module 240 to transition to a closed state (e.g., the folded state of FIG. 3A) in case that a pressing force is provided in a folding direction (direction C) in a state in which the electronic device 200 is unfolded at a predetermined inflection angle. In an embodiment, the electronic device 200 may be operated to maintain the unfolded state at various angles through the hinge module 240.

Referring to FIG. 4, the electronic device 200 may include a first side frame 213, a second side frame 223, and a hinge module 240 rotatably connecting the first side frame 213 and the second side frame 223. According to an embodiment, the electronic device 200 may include a first support plate 2131 at least partially extending from the first side frame 213 and a second support plate 2231 at least partially extending from the second side frame 223. According to an embodiment, the first support plate 2131 may be integrally formed with the first side frame 213 or may be structurally coupled with the first side frame 213. Similarly, the second support plate 2231 may be integrally formed with the second side frame 223 or may be structurally coupled with the second side frame 223.

According to an embodiment, the electronic device 200 may include the flexible display 300 disposed to be supported by, directly or indirectly, the first support plate 2131 and the second support plate 2231. According to an embodiment, the electronic device 200 may include a first rear cover 214 coupled to the first side frame 213 and providing a first space between it and the first support plate 2131 and a second rear cover 224 coupled to the second side frame 223 and providing a second space between it and the second support plate 2231. In an embodiment, the first side frame 213 and the first rear cover 214 may be integrally formed. In an embodiment, the second side frame 223 and the second rear cover 224 may be integrally formed. According to an embodiment, the electronic device 200 may include a first housing 210 (e.g., a first housing structure) provided through the first side frame 213, the first support plate 2131, and the first rear cover 214. According to an embodiment, the electronic device 200 may include a second housing 220 (e.g., a second housing structure) provided through the second side frame 223, the second support plate 2231, and the second rear cover 224. According to an embodiment, the electronic device 200 may include a sub display 231 disposed to be visible from the outside through at least a partial area of the first rear cover 214.

According to an embodiment, the electronic device 200 may include a first substrate assembly 261 (e.g., a main printed circuit board), a camera assembly 263, a first battery 271, or a first bracket 251 disposed in a first space between the first side frame 213 and the first rear cover 214.

According to an embodiment, the camera assembly 263 may include a plurality of camera devices (e.g., the camera devices (e.g., the first camera device 205 and/or the second camera device 208) of FIGS. 2A and 3A), and may be electrically connected, directly or indirectly, to the first substrate assembly 261.

According to an embodiment, the first bracket 251 may provide a support structure and enhanced rigidity for supporting the first substrate assembly 261 and/or the camera assembly 263.

According to an embodiment, the electronic device 200 may include a second substrate assembly 262 (e.g., a sub printed circuit board), an antenna 290 (e.g., a coil member), a second battery 272, or a second bracket 252 disposed in a second space between the second side frame 223 and the second rear cover 224.

According to an embodiment, the electronic device 200 may include a wiring member 280 (e.g., a flexible printed circuit board (FPCB)). The wiring member 280 according to an embodiment may be disposed to extend from the first substrate assembly 261 across the hinge module 240 to a plurality of electronic components (e.g., the second substrate assembly 262, the second battery 272, or the antenna 290) disposed between the second side frame 223 and the second rear cover 224.

According to an embodiment, the first substrate assembly 261, the second substrate assembly 262, and the wiring member 280 may be electrically connected, operatively connected, directly or indirectly, or integrally formed with each other. According to an embodiment, as the first substrate assembly 261 and the second substrate assembly 262 are integrally formed to transmit and receive an electrical signal or wavelength, the wiring member 280 may be omitted.

According to an embodiment, the electronic device 200 may include one or more batteries (e.g., the first battery 271 and/or the second battery 272). For example, one or more batteries may include at least one of a first battery 271 disposed in an area corresponding to the first housing 210 and a second battery 272 disposed in an area corresponding to the second housing 220. The electronic device 200 according to an embodiment may include any one of the first battery 271 and/or the second battery 272, or may include both the first battery 271 and/or the second battery 272.

According to an embodiment, the electronic device 200 may include a flexible battery. The flexible battery may be disposed over at least a portion of each of the first housing 210 and the second housing 220. The flexible battery may be disposed to overlap a portion of an area corresponding to the first housing 210 and a portion of an area corresponding to the second housing 220. The flexible battery may include a battery hinge portion at a boundary at which the first housing 210 and the second housing 220 are separated from each other. The battery hinge portion may be formed to be physically thin. The battery hinge portion is provided at a position corresponding to the folding axis (e.g., axis F), so that the flexible battery may be folded as the electronic device 200 is folded.

According to an embodiment, the battery hinge portion of the flexible battery may be a physical or electrical connector. The flexible battery may include a first battery section, a second battery section, and a connector electrically or operatively connecting the first battery section and the second battery section. The first battery section and the second battery section may be electrically or operatively connected to each other through a connector. The connector may be a component constituting the flexible battery and may be provided outside or inside the flexible battery. However, according to an embodiment, the connector may physically connect the first battery section and the second battery section as a non-conductive line connector.

According to an embodiment, the antenna 290 may include a near field communication (NFC) antenna, a wireless charging antenna, and/or a magnetic secure transmission (MST) antenna. For example, the antenna 290 may perform short-range communication with an external device or may wirelessly transmit and receive power required for charging.

According to an embodiment, the electronic device 200 may include a hinge housing 241 (e.g., a hinge cover) that supports the hinge module 240, is exposed to the outside in case that the electronic device 200 is in a folded state (e.g., the folded state of FIG. 3A), and is drawn in a first space and/or a second space not to be visible from the outside in case that the electronic device 200 is in an unfolded state (e.g., the unfolded state of FIG. 2A).

According to an embodiment, the electronic device 200 may include a first protective cover 215 coupled along an edge of the first side frame 213. According to an embodiment, the electronic device 200 may include a second protective cover 225 coupled along an edge of the second side frame 223. According to an embodiment, an edge of the first flat portion (e.g., the first flat portion 230a of FIG. 2B) of the flexible display 300 may be protected by the first protective cover 215. According to an embodiment, an edge of the second flat portion (e.g., the second flat portion 230b of FIG. 2B) of the flexible display 300 may be protected by the second protective cover 225. According to an embodiment, the electronic device 200 may include a protective cap 235 disposed to protect an edge of a bendable portion (e.g., the bendable portion 230c of FIG. 2B) corresponding to the hinge module 240 of the flexible display 300.

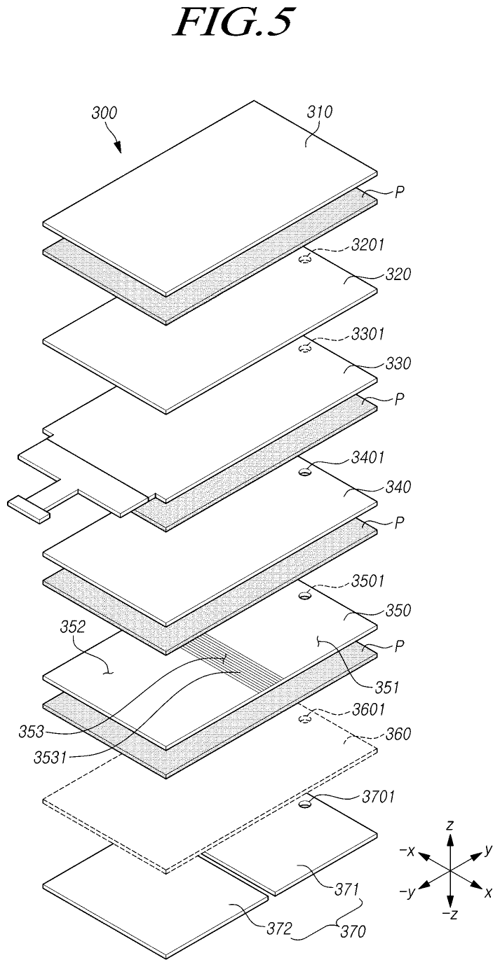

FIG. 5 is an exploded perspective view illustrating a flexible display according to various example embodiments.

Referring to FIG. 5, a flexible display 300 according to various embodiments may include a window layer 310, a polarizer 320, a display panel 330, a polymer layer 340, a metal sheet layer 350, and a reinforcement plate 370 sequentially disposed on, directly or indirectly, a rear surface (e.g., a surface facing the −z axis) of the window layer 310.

According to an embodiment, the window layer 310, the polarizer 320, the display panel 330, the polymer layer 340, and the metal sheet layer 350 may be disposed to cross at least a portion of the first surface (e.g., the first surface 211 of FIG. 2A) of the first housing (e.g., the first housing 210 of FIG. 2A) and the third surface (e.g., the third surface 221 of FIG. 2A) of the second housing (e.g., the second housing 220 of FIG. 2A).

According to an embodiment, the reinforcement plate 370 may include a first reinforcement plate 371 facing the first housing 210 and a second reinforcement plate 372 facing the second housing 220.

According to an embodiment, the window layer 310, the polarizer 320, the display panel 330, the polymer layer 340, the metal sheet layer 350, and the reinforcement plate 370 may be attached to each other through an adhesive P. For example, the adhesive P may include at least one of optical clear adhesive (OCA), pressure sensitive adhesive (PSA), heat-reactive adhesive, general adhesive, and/or double-sided tape.

According to an embodiment, the display panel 330 may include a plurality of pixels and a line structure (e.g., electrode pattern). According to an embodiment, the polarizer 320 may selectively pass light generated from a light source of the display panel 330 and vibrating in a predetermined direction. According to an embodiment, the display panel 330 and the polarizer 320 may be integrally formed. According to an embodiment, the flexible display 300 may include a touch panel (not illustrated).

According to an embodiment, the polymer layer 340 may be disposed below the display panel 330 (e.g., in the −z-axis direction). For example, the polymer layer 340 may provide a dark background for securing visibility of the display panel 330. Further, the polymer layer 340 may be formed of a cushioning material for cushioning action. In an embodiment, for waterproofing of the flexible display 300, the polymer layer 340 may be removed or disposed below the metal sheet layer 350.

According to an embodiment, the metal sheet layer 350 may be formed in a shape providing flexibility to the flexible display 300. According to an embodiment, the metal sheet layer 350 may include at least one of stainless steel (STS), Cu, Al, or metal CLAD (e.g., a stacked member with alternating STS and Al).

According to an embodiment, the metal sheet layer 350 may include a first flat portion 351 corresponding to the first housing 210, a second flat portion 352 corresponding to the second housing 220, and a bending portion 353 connecting the first flat portion 351 and the second flat portion 352.

According to an embodiment, the bending portion 353 may include a plurality of openings 3531 disposed at designated intervals. According to an embodiment, bending characteristics of the bending portion 353 may be determined through at least one of size, shape, or arrangement density of at least some openings among the plurality of openings 3531. In an embodiment, the metal sheet layer 350 may include other alloy materials. In an embodiment, the metal sheet layer 350 may help reinforce rigidity of the electronic device (e.g., the electronic device 200 of FIG. 2A), shield ambient noise, and be used to disperse heat emitted from surrounding heat-emitting components. In an embodiment, the metal sheet layer 350 may be replaced with a non-metallic thin plate material such as fiber reinforced plastics (FRP) (e.g., carbon fiber reinforced plastics (CFRP) or glass fiber reinforced plastics (GFRP)) having rigid characteristics for supporting the display panel 330.

According to an embodiment, the flexible display 300 may include a digitizer 360 as a detection member disposed below the metal sheet layer 350 (e.g., in the −z-axis direction) and receiving input from an electronic pen (e.g., stylus). The digitizer 360 may include, e.g., a coil member disposed on, directly or indirectly, a dielectric substrate to detect an electromagnetic induction type resonance frequency applied from an electronic pen.

In an embodiment, the digitizer 360 may be disposed between the polymer layer 340 and the metal sheet layer 350, but the disclosure is not limited thereto. For example, the digitizer 360 may be disposed between the metal sheet layer 350 and the reinforcement plate 370.

According to an embodiment, the flexible display 300 may include at least one functional member (not illustrated) disposed between the polymer layer 340 and the metal sheet layer 350, or below the metal sheet layer 350 (e.g., in the −z-axis direction). The functional member may include, e.g., a graphite sheet for heat dissipation, an added display, a force touch FPCB, a fingerprint sensor FPCB, a communication antenna radiator, or conductive/non-conductive tape. In an embodiment, in case that the functional member may not be bent, it may be separately disposed in the first housing 210 and the second housing 220. In an embodiment, in case that the functional member may be bent, it may be disposed from the first housing 210 through the hinge module (e.g., the hinge module 240 of FIG. 4) to at least a portion of the second housing 220.

According to an embodiment, the electronic device 200 may include a camera device (e.g., the first camera device 205 of FIG. 2A) disposed below the flexible display 300 and detecting an external environment through the flexible display 300.

According to an embodiment, the electronic device 200 may include at least one sensor module (e.g., the sensor module 204 of FIG. 2A) (e.g., an illuminance sensor, a proximity sensor, or a TOF sensor) disposed below the flexible display 300.

According to an embodiment, the polarizer 320, the display panel 330, the polymer layer 340, the metal sheet layer 350, the digitizer 360, and the reinforcement plate 370 may include through holes 3201, 3301, 3401, 3501, 3601, 3701. In an embodiment, the display panel 330 and/or the polarizer 320 may not require the through holes 3201, 3301 through transmittance adjustment of the corresponding area. In an embodiment, the size of the through holes 3201, 3301, 3401, 3501, 3601, 3701 may be formed based on the size of the camera device 205 and/or the angle of view of the camera device 205, and the size of each through hole 3201, 3301, 3401, 3501, 3601, 3701 may be different from each other.

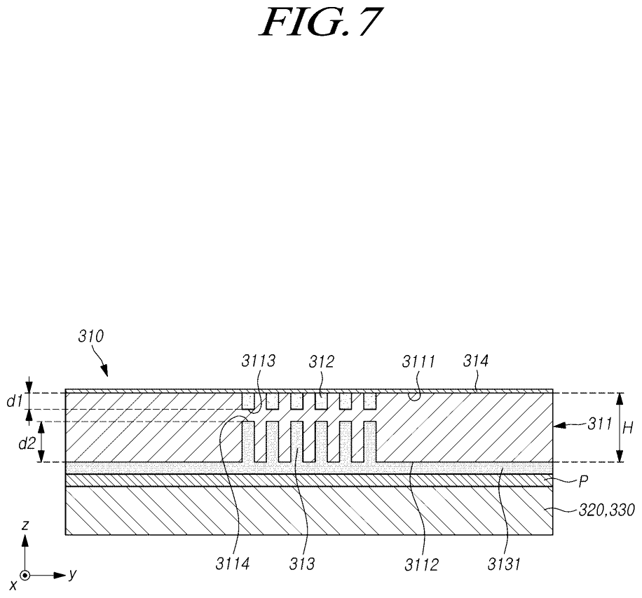

According to an embodiment, the window layer 310 may include a glass layer (e.g., the glass layer 311 of FIG. 7). According to an embodiment, the glass layer 311 may be disposed in an area corresponding to a bendable portion (e.g., the bendable portion 230c of FIG. 2B) of the flexible display 300 and include a plurality of patterns (e.g., the plurality of first patterns 3113 and the plurality of second patterns 3114 of FIG. 7) formed lower than the surface of the glass layer 311, thereby helping enhance touch feeling and/or flexibility of the flexible display 300.

According to an embodiment, the plurality of patterns 3113, 3114 may be filled with filling members (e.g., the first filling member 312 and the second filling member 313 of FIG. 7) having different modulus, hardness, or molecular weight for each pattern, thereby enhancing touch feeling and/or flexibility of the flexible display 300.

Hereinafter, the window layer 310 is described in detail.

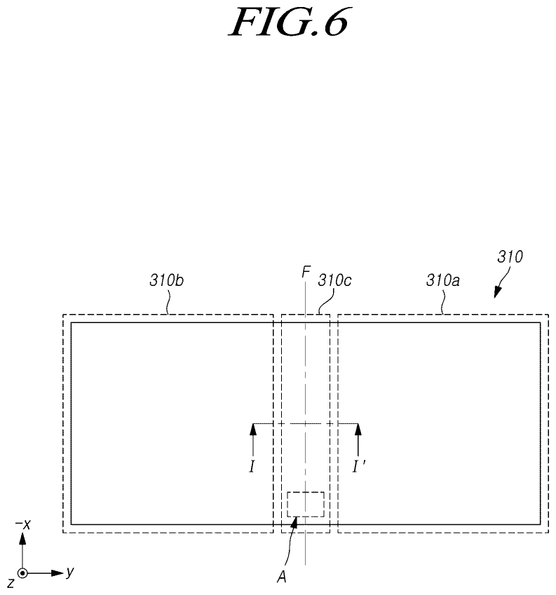

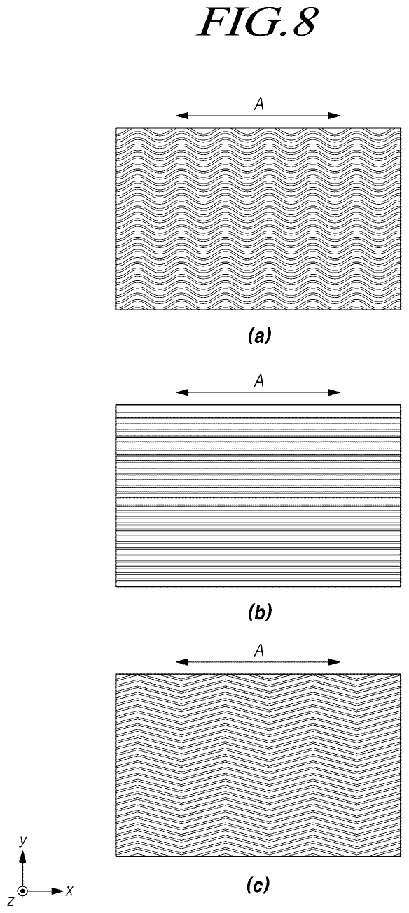

FIG. 6 is a plan view illustrating a window layer according to various example embodiments. FIG. 7 is a cross-sectional view taken along line I-I′ of FIG. 6. FIG. 8 is an enlarged view illustrating portion A illustrated in FIG. 6.

Referring to FIGS. 6 to 8, a window layer 310 according to an embodiment may include a first area 310a corresponding to the first housing (e.g., the first housing 210 of FIG. 2A) of the electronic device (e.g., the electronic device 200 of FIG. 2A), a second area 310b corresponding to the second housing (e.g., the second housing 220 of FIG. 2A), and a third area 310c corresponding to the bendable portion (e.g., the bendable portion 230c of FIG. 2B).

According to an embodiment, the third area 310c may be bendably deformed together with the display panel (e.g., the display panel 330 of FIG. 5) according to a folding operation of the electronic device 200 based on a folding axis F.

According to an embodiment, the window layer 310 may include a glass layer 311 including a first surface 3111 facing an external direction (e.g., +z-axis direction) of the electronic device 200 and a second surface 3112 facing a direction (e.g., −z-axis direction) toward the display panel 330 opposite to the first surface 3111.

According to an embodiment, the polarizer 320 and/or the display panel 330 may be stacked below the glass layer 311 (e.g., in the −z-axis direction). In an embodiment, the glass layer 311 (or the second planarization layer 3131) and the polarizer 320 and/or the display panel 330 may be attached to each other through the adhesive P.

According to an embodiment, a coating layer 314 may be stacked on the first surface 3111 of the glass layer 311. According to an embodiment, the coating layer 314 may include at least one of a hard coating layer and/or an anti-fingerprint layer. In an embodiment, the coating layer 314 may be composed of a material having a higher hardness value than the glass layer 311 and/or the first filling member 312 to be described below. For example, the coating layer 314 may have a surface hardness of H (hardness) or higher. In an embodiment, a compound for fingerprint prevention may be coated on the surface of the coating layer 314. In an embodiment, the coating layer 314 may have hydrophobicity with a water contact angle of 95 degrees or more.

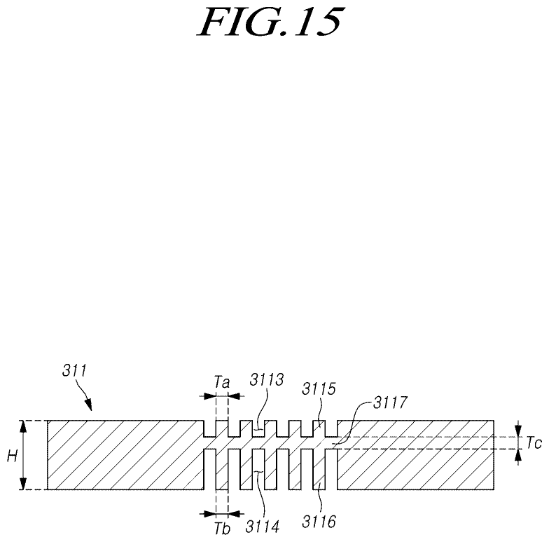

According to an embodiment, the glass layer 311 may include a plurality of first patterns 3113 formed lower than the first surface 3111 from the first surface 3111 and spaced apart at predetermined intervals. According to an embodiment, the glass layer 311 may include a plurality of second patterns 3114 formed lower than the second surface 3112 from the second surface 3112 and spaced apart at predetermined intervals. In an embodiment, the plurality of first patterns 3113 and the plurality of second patterns 3114 may be disposed to be spaced apart from each other with a thin portion (e.g., the third spacer 3117 of FIG. 15) of the glass layer 311 therebetween.

According to an embodiment, the plurality of first patterns 3113 and the plurality of second patterns 3114 may be positioned in the third area 310c of the window layer 310. For example, the plurality of first patterns 3113 and the plurality of second patterns 3114 may be positioned in an area of the glass layer 311 corresponding to the bendable portion (e.g., the bendable portion 230c of FIG. 2B) of the flexible display (e.g., the flexible display 300 of FIG. 2B).

According to an embodiment, the plurality of first patterns 3113 and the plurality of second patterns 3114 may have various shapes. For example, the plurality of first patterns 3113 and the plurality of second patterns 3114 may be formed extending along the folding axis F to have a wave shape, as illustrated in (a) of FIG. 8. In an example, the plurality of first patterns 3113 and the plurality of second patterns 3114 may be formed extending along the folding axis F to have a straight line (e.g., horizontal line) shape, as illustrated in (b) of FIG. 8. In an example, the plurality of first patterns 3113 and the plurality of second patterns 3114 may be formed extending along the folding axis F to have a zigzag (or chevron) shape, as illustrated in (c) of FIG. 8.

According to an embodiment, the window layer 310 may include a first filling member 312 filling the plurality of first patterns 3113. According to an embodiment, the window layer 310 may include a second filling member 313 filling the plurality of second patterns 3114.

According to an embodiment, the first filling member 312 and the second filling member 313 may include an elastic material. In an embodiment, the first filling member 312 and the second filling member 313 may be substantially transparent materials, including materials that are filling the patterns 3113, 3114 initially in liquid or semi-solid form and then cured over time, by light irradiation, or through chemical treatment. The first filling member 312 and the second filling member 313 may include, e.g., resin such as silicon, urethane, or acrylic. The first filling member 312 and the second filling member 313 may correspond to optically clear resin (OCR).

According to an embodiment, the first filling member 312 may have substantially the same modulus, hardness, or molecular weight as the modulus, hardness, or molecular weight of the glass layer 311 to reduce a difference in touch feeling between the glass layer 311 and the filling member 312. For example, the first filling member 312 may have a modulus of 20 MPa to 400 MPa. In case that a user touches (or swipes) the display, deformation/micro-movement of the filling member 312 may be decreased, thereby reducing a difference in touch feeling between the glass layer 311 and the first filling member 312.

According to an embodiment, the second filling member 313 may have a different modulus, hardness, or molecular weight from the first filling member 312. In an embodiment, the second filling member 313 may have a lower modulus, hardness, or molecular weight than the modulus, hardness, or molecular weight of the first filling member 312. For example, in case that the first filling member 312 has a modulus of 20 to 400 MPa, the second filling member 313 may be designed to have a modulus of 0.005 to 10 MPa.

For example, in case that the first filling member 312 and the second filling member 313 have the same modulus of 400 MPa, a folding resistance (or repulsive force) of 1.1532e [N·mm] may be applied to the bendable portion 230c of the flexible display 300. For example, in case that the first filling member 312 has a modulus of 400 MPa and the second filling member 313 has a modulus of 0.03 MPa, a folding resistance (or repulsive force) of 1.1532e [N·mm] may be applied to the bendable portion 230c of the flexible display 300. Compared to the case where the first filling member 312 and the second filling member 313 have the same modulus of 400 MPa, the folding resistance may be improved (decreased) by 24%.

As a result, by designing the modulus, hardness, or molecular weight of the second filling member 313 to be lower than that of the first filling member 312, the increasing folding resistance (or repulsive force) as the modulus, hardness, or molecular weight of the first filling member 312 increases may be offset.

According to an embodiment, the plurality of first patterns 3113 may be formed recessed to have a predetermined depth d1 from the first surface 3111. According to an embodiment, the plurality of second patterns 3114 may be formed recessed to have a predetermined depth d2 from the second surface 3112.

According to an embodiment, a depth d1 of the plurality of first patterns 3113 and a depth d2 of the plurality of second patterns 3114 may be substantially the same.

According to an embodiment, a depth d1 of the plurality of first patterns 3113 and a depth d2 of the plurality of second patterns 3114 may be different. In an embodiment, a depth d1 of the plurality of first patterns 3113 may be shallower than a depth d2 of the plurality of second patterns 3114 (see FIG. 7).

For example, in case that the first filling member 312 has a modulus of 400 MPa, the second filling member 313 has a modulus of 0.03 MPa, and the depths of the plurality of patterns 3113, 3114 are the same (d1=d2), a folding resistance (or repulsive force) of 1.1532e [N·mm] may be applied to the bendable portion 230c of the flexible display 300.

For example, in case that the first filling member 312 has a modulus of 400 MPa, the second filling member 313 has a modulus of 0.03 MPa, and the depths of the plurality of patterns 3113, 3114 are different (d1≠d2), e.g., in case that a ratio of the depth d1 of the plurality of first patterns 3113 to the depth d2 of the plurality of second patterns 3114 is 1:2.2, a folding resistance (or repulsive force) of 6.4054e⁻¹ [N·mm] may be applied to the bendable portion 230c of the flexible display 300. Compared to the case where the first filling member 312 has a modulus of 400 MPa, the second filling member 313 has a modulus of 0.03 MPa, and the depths of the plurality of patterns 3113, 3114 are the same, the folding resistance may be improved (decreased) by 27%. Further, compared to the case where the first filling member 312 and the second filling member 313 have the same modulus of 400 MPa and the depths of the plurality of patterns 3113, 3114 are the same, the folding resistance may be improved (decreased) by 44%.

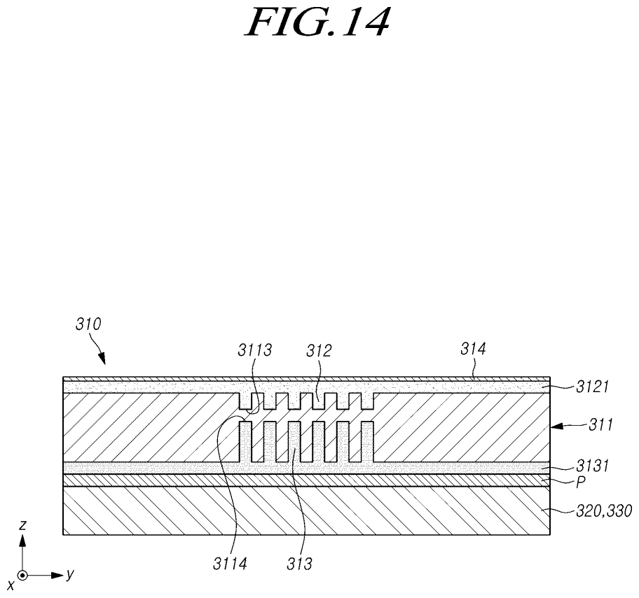

According to an embodiment, a first planarization layer (e.g., the first planarization layer 3121 of FIG. 14) may be stacked on the first surface 3111 of the glass layer 311. As illustrated in FIG. 7, the first planarization layer may be omitted. Hereinafter, an embodiment in which the first planarization layer 3121 is stacked on the window layer 310 is described below with reference to FIG. 14.

According to an embodiment, a second planarization layer 3131 may be stacked on the second surface 3112 of the glass layer 311. In an embodiment, the second planarization layer 3131 may induce the second surface 3112 roughened by the second filling member 313 filling the plurality of second patterns 3114 to have a substantially flat surface. In an embodiment, the second planarization layer 3131 may be composed of substantially the same material as the second filling member 313. The second planarization layer 3131 may be formed together in case that the second filling member 313 is filling the plurality of second patterns 3114.

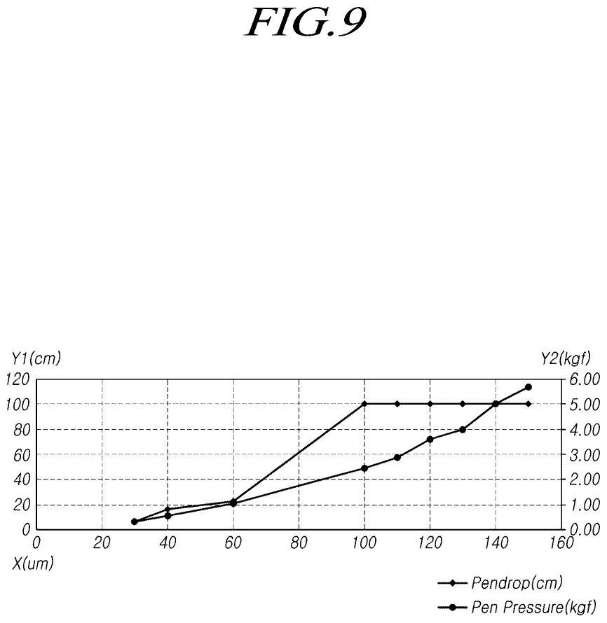

FIG. 9 is a graph illustrating strength simulation results by thickness of a glass layer according to an example embodiment.

The X-axis of FIG. 9 represents the thickness (e.g., H of FIG. 7) of the glass layer (e.g., the glass layer 311 of FIG. 7), the Y1-axis of FIG. 9 (the Y-axis corresponding to the left side of the graph) represents pen drop height (cm), and the Y2-axis of FIG. 9 (the Y-axis corresponding to the right side of the graph) represents pen pressure force (kgf). In this case, the specification of the pen used in the simulation may satisfy 5.8 g and 0.3pi.

Referring to FIG. 9, a thickness H of the glass layer (e.g., the glass layer 311 of FIG. 7) according to an embodiment may be designed to be 100 μm or more. In this case, the glass layer 311 may satisfy impact resistance of a pen drop height of 100 cm and 2.7 kgf or more.

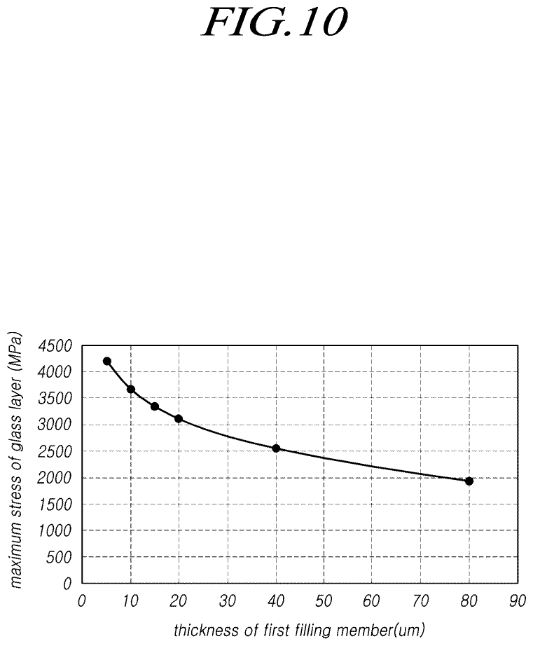

FIG. 10 is a graph illustrating pen pressure simulation results by thickness of a first filling member according to an example embodiment.

The X-axis of FIG. 10 represents the thickness (μm) of the first filling member (e.g., the first filling member 312 of FIG. 7), and the Y-axis of FIG. 10 represents the maximum stress (or breaking strength) (MPa) of the glass layer (e.g., the glass layer 311 of FIG. 7).

Referring to FIG. 10, a thickness of the first filling member 312 according to an example embodiment may be designed to be 20 μm or more. Here, the thickness of the first filling member 312 may mean substantially the same value as the depth d1 of the plurality of first patterns (e.g., the plurality of first patterns 3113 of FIG. 7). In this case, the maximum stress (or breaking strength) of the glass layer 311 satisfies 3000 MPa and may maintain a pen pressure (5.8 g, 0.3pi) strength of 0.3 kgf or more.

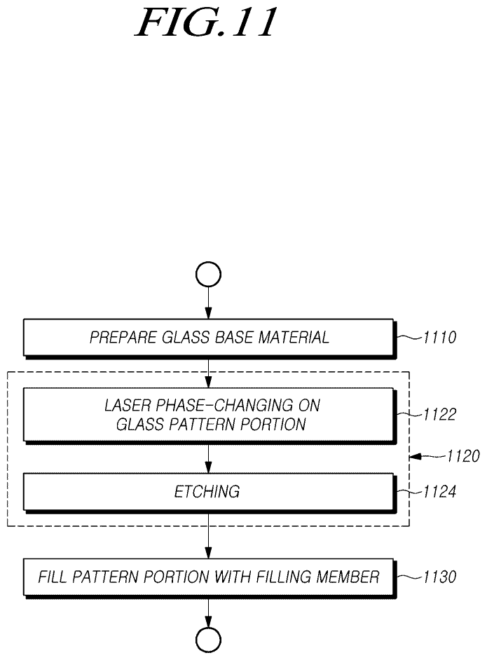

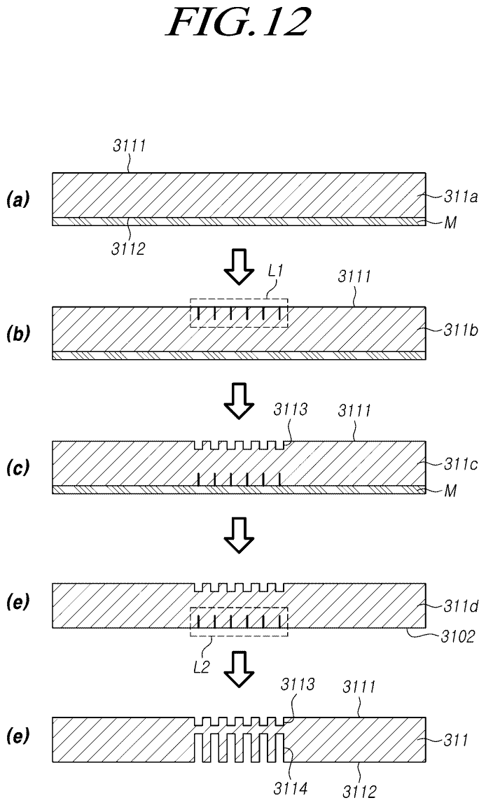

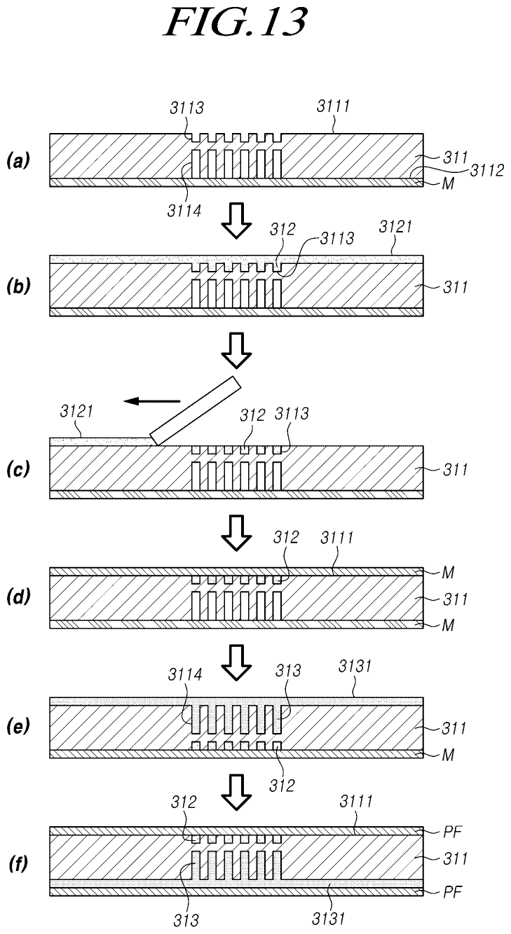

FIG. 11 is a manufacturing process diagram illustrating a window layer according to an example embodiment. FIG. 12 is a view illustrating a process of forming a plurality of patterns in a glass layer according to an example embodiment. FIG. 13 is a view illustrating a process of filling a plurality of patterns with a filling member according to an example embodiment.

Referring to FIG. 11, for manufacturing the window layer (e.g., the window layer 310 of FIG. 5), a glass base material (e.g., the glass base material 311a of FIG. 12) may be prepared (1110). According to an embodiment, the glass base material 311a may be prepared with a thickness having pressure resistance characteristics according to contact (or pressure) of an external electronic device (e.g., electronic pen) while protecting the display. For example, the glass base material 311a may be designed to have a thickness of 100 μm or more.

According to an embodiment, the manufacturing process of the window layer may include a process of forming a plurality of patterns (e.g., the plurality of first patterns 3113 and the plurality of second patterns 3114 of FIG. 7) in the glass layer 311 (1120). According to an embodiment, the process 1120 of forming the plurality of patterns 3113, 3114 in the glass layer 311 may include a process 1122 of forming pattern lines through laser in pattern portions (or pattern areas) L1, L2 of the glass base material 311a. According to an embodiment, the process 1120 of forming the plurality of patterns 3113, 3114 in the glass layer 311 may include a process 1124 of etching the pattern lines.

Hereinafter, with reference to (a) to (e) of FIG. 12, the manufacturing process 1120 for forming the plurality of patterns 3113, 3114 in the glass layer 311 is described.

According to an embodiment, a masking member M may be attached to the second surface 3112 of the glass base material 311a to prevent etching (see (a) of FIG. 12).

According to an embodiment, a plurality of pattern lines may be formed by irradiating laser or Bessel beam at predetermined intervals to the pattern portion L1 positioned on the first surface 3111 of the glass base material 311a (see (b) of FIG. 12). For example, a plurality of pattern lines may be vertically phase-changed in the pattern portion L1 of the glass base material 311a by laser or Bessel beam. Here, the pattern portion L1 may mean an area corresponding to the third area (e.g., the third area 310c of FIG. 6) of the window layer 310.

According to an embodiment, the plurality of first patterns 3113 may be formed by dipping the glass base material 311b with pattern lines formed on the first surface 3111 in an etching solution (see (c) of FIG. 12). Here, the etching solution may include various acid/basic solutions. For example, the etching solution may include ammonium fluoride (NH4F), sulfuric acid (H2SO4), nitric acid (HNO3), fluorosilicic acid (H2SiF6), sodium hydroxide (NaOH), and/or hydrofluoric acid (HF). The etching solution may penetrate into the plurality of pattern lines phase-changed by laser or Bessel beam to form the plurality of first patterns 3113 having a predetermined depth.

According to an embodiment, after removing the masking member M attached to the second surface 3112 of the glass base material 311c, a plurality of pattern lines may be formed by irradiating laser or Bessel beam at predetermined intervals to the pattern portion L2 positioned on the second surface 3112 of the glass base material 311c (see (d) of FIG. 12).

According to an embodiment, the plurality of second patterns 3114 may be formed by dipping the glass base material 311d with pattern lines formed on the second surface 3112 in an etching solution (see (e) of FIG. 12).

According to an embodiment, the manufacturing process of the window layer may include a process of filling the filling members 312, 313 in the plurality of patterns 3113, 3114 provided in the glass layer 311 (1130).

Hereinafter, with reference to (a) to (f) of FIG. 13, the manufacturing process for filling the filling members 312, 313 in the glass layer 311 is described.

According to an embodiment, after attaching the masking member M to the second surface 3112 of the glass layer 311 (see (a) of FIG. 13), the first filling member 312 may be applied over the first surface 3111 (see (b) of FIG. 13). In this case, the first filling member 312 may be filling the plurality of first patterns 3113 provided on the first surface 3111.

According to an embodiment, to enhance the texture of the glass layer 311, excess first filling member (e.g., the first planarization layer 3121) may be removed along with bubbles (see (c) of FIG. 13).

According to an embodiment, after attaching the masking member M to the first surface 3111 of the glass layer 311, the first filling member 312 may be cured for a predetermined time (see (d) of FIG. 13).

According to an embodiment, after separating the masking member M attached to the second surface 3112 of the glass layer 311, the glass layer 311 may be flipped upside down and the second filling member 313 may be applied over the second surface 3112 (see (e) of FIG. 13).

According to an embodiment, after removing bubbles and separating the masking member M attached to the first surface 3111, the second filling member 313 may be cured for a predetermined time. Thereafter, protective vinyl PF may be attached to two opposite surfaces 3111, 3112 of the glass layer 311 (see (f) of FIG. 13).

FIG. 14 is a cross-sectional view illustrating a flexible display according to an example embodiment.

Referring to FIG. 14, a first planarization layer 3121 may be stacked on the first surface 3111 of the glass layer 311 according to an embodiment.

According to an embodiment, the first planarization layer 3121 may induce the first surface 3111 roughened by the first filling member 312 filling the plurality of first patterns 3113 to have a substantially flat surface. In an embodiment, the first planarization layer 3121 may be composed of substantially the same material as the first filling member 312. The first planarization layer 3121 may be formed together in case that the first filling member 312 is filling the plurality of first patterns 3113.

As the entire first surface 3111 of the glass layer 311 is exposed with the same material, a difference in touch feeling between areas across the entire area (e.g., the first area 310a to the third area 310c of FIG. 6) of the window layer (e.g., the window layer 310 of FIG. 6) may be alleviated.

Further, in the manufacturing process of the window layer, unlike illustrated in (c) of FIG. 13, process costs may be decreased as the process of removing excess first filling member 312 is eliminated.

According to an embodiment, a thickness of the first planarization layer 3121 may have a range of 10 to 30 μm. In case that the thickness of the first planarization layer 3121 is appropriately set, loss of touch feeling due to the texture of the glass layer 311 may be alleviated.

FIG. 15 is a cross-sectional view illustrating a glass layer according to an example embodiment.

Referring to FIG. 15, in an embodiment, a first spacer 3115 may be formed between the plurality of first patterns 3113. In an embodiment, the first spacer 3115 may be formed together in case of forming the plurality of first patterns 3113. In an embodiment, a thickness Ta of the first spacer 3115 may mean an interval between the plurality of first patterns 3113.

According to an embodiment, a second spacer 3116 may be formed between the plurality of second patterns 3114. In an embodiment, the second spacer 3116 may be formed together in case of forming the plurality of second patterns 3114. In an embodiment, a thickness Tb of the second spacer 3116 may mean an interval between the plurality of second patterns 3114. In an embodiment, the thicknesses Ta, Tb of the first spacer 3115 and the second spacer 3116 may be substantially the same, but the disclosure is not limited thereto.

According to an embodiment, a third spacer 3117 may be formed between the plurality of first patterns 3113 and the plurality of second patterns 3114. In an embodiment, the plurality of first patterns 3113 and the plurality of second patterns 3114 may be disposed to be spaced apart from each other by a predetermined distance Tc with the third spacer 3117 therebetween. According to an embodiment, the third spacer 3117 between the plurality of first patterns 3113 and the plurality of second patterns 3114 may be formed as a surface substantially parallel to the glass layer 311. For example, the first spacer 3115 may be formed substantially perpendicular to the third spacer 3117. For example, the second spacer 3116 may be formed substantially perpendicular to the third spacer 3117. The first spacer 3115 and the second spacer 3116 may extend in opposite directions with respect to the third spacer 3117.

According to an embodiment, the glass layer 311 may have its surface chemically strengthened by alkali ion exchange for protection of the display. Here, the alkali ion may include K+ ions. By substituting Na+ ions inside the glass layer 311 with K+ ions, compressive stress is formed on the surface of the glass layer 311, thereby enhancing impact resistance strength of the glass layer 311. In this case, chemical strengthening treatment of the glass layer 311 may proceed based on the thinnest portion (thin portion) of the configuration of the glass layer 311, e.g., the above-described spacers 3115, 3116, 3117.

TABLE 1

| Thickness (μm) | Compressive Stress (MPa) |
|---|---|
| 15 | 175 |
| 20 | 350 |
| 25 | 525 |
| 30 | 700 |
| 35 | 875 |
| 40 | 1050 |
| 45 | 1225 |
| 50 | 1400 |

[Table 1] above is a table showing compressive stress applied to the thick portion of the glass layer 311 by thickness of the spacers 3115, 3116, 3117. According to an embodiment, the first spacer 3115, the second spacer 3116, and the third spacer 3117 may be formed to have a predetermined thickness for chemical strengthening treatment. In an embodiment, the thickness of the first spacer 3115, the second spacer 3116, and the third spacer 3117 may be designed to be 30 μm or more. In this case, as described in [Table 1] above, a compressive stress of 700 MPa, which is a compressive stress of 600 MPa or more, may be applied to the thick portion of the glass layer 311. Accordingly, during chemical strengthening treatment, self-breaking phenomenon where the glass layer 311 breaks by itself due to tensile stress generated inside the glass layer 311 may be prevented.

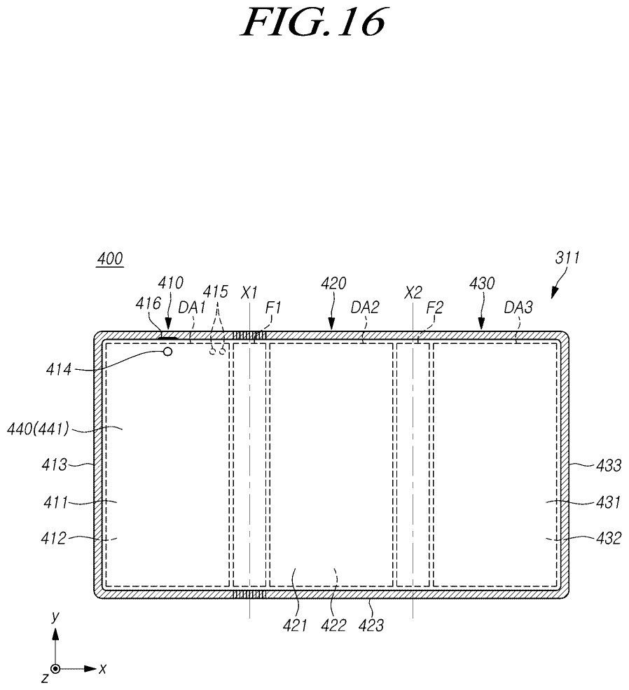

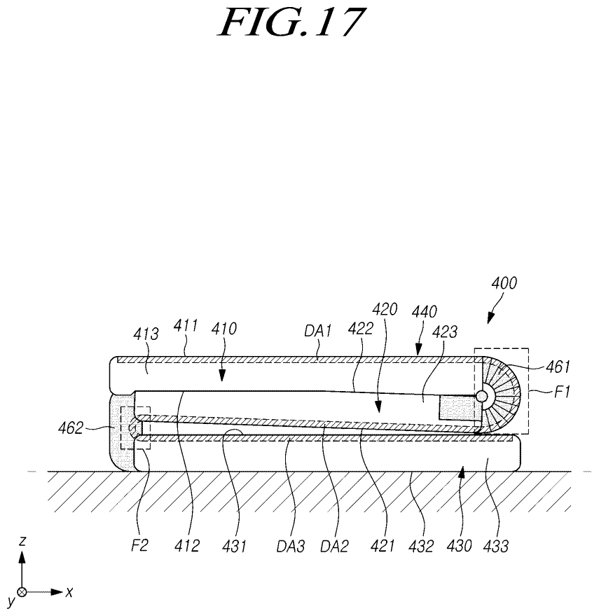

FIG. 16 is a view schematically illustrating an electronic device in an unfolded state according to an example embodiment. FIG. 17 is a view schematically illustrating the electronic device of FIG. 16 in a folded state according to an example embodiment.

Referring to FIGS. 16 and 17, an electronic device 400 according to an embodiment may include a first housing 410, a second housing 420, and a third housing 430 disposed rotatably with respect to each other.

According to an embodiment, the electronic device 400 may include a flexible display 440 disposed to receive support from the first housing 410, the second housing 420, and the third housing 430.

According to an embodiment, the first housing 410 and the second housing 420 may be rotatably connected to each other, directly or indirectly, based on a first folding axis X1 through a first hinge module 461.

According to an embodiment, the second housing 420 and the third housing 430 may be rotatably connected to each other, directly or indirectly, based on a second folding axis X2 through a second hinge module 462.

According to an embodiment, the first housing 410 and the second housing 420 may be operated in a first folding manner (e.g., out-folding manner) through the first hinge module 461. For example, the first housing 410 and the second housing 420 may be disposed facing opposite directions from each other so that display areas facing each housing 410, 420 may be seen from the outside in a folded state.

According to an embodiment, the second housing 420 and the third housing 430 may be operated in a second folding manner (e.g., in-folding manner) through the second hinge module 462. For example, the second housing 420 and the third housing 430 may be disposed so that display areas facing each housing 420, 430 face each other in a folded state.

According to an embodiment, the electronic device 400 may be operated with the first housing 410, the second housing 420, and the third housing 430 completely unfolded. According to an embodiment, the electronic device 400 may be operated with only the first housing 410 and the second housing 420 folded. According to an embodiment, the electronic device 400 may be operated with all of the first housing 410, the second housing 420, and the third housing 430 folded.

According to an embodiment, a display area facing the first housing 410 may be disposed toward the outside of the electronic device 400 to be visible to a user in a fully folded state. In case that the electronic device 400 is in a folded state, a camera module 414 and a sensor module 415 may be disposed to detect an external environment through the display area corresponding to the first housing 410. In an embodiment, the camera module 414 and/or the sensor module 415 may be disposed below the flexible display 440, invisible from the outside.

According to an embodiment, the flexible display 440 may include a glass layer 441 (e.g., the glass layer 311 of FIG. 7) stacked thereon to protect the display panel (e.g., the display panel 330 of FIG. 7) and provide flexibility.

According to an embodiment, the glass layer 441 may include a first area DA1 facing the first housing 410, a second area DA2 facing the second housing 420, and a third area DA3 facing the third housing 430.

According to an embodiment, the glass layer 441 may include a first folding area F1 facing the first hinge module 461 between the first area DA1 and the second area DA2, and a second folding area F2 facing the second hinge module 462 between the second area DA2 and the third area DA3.

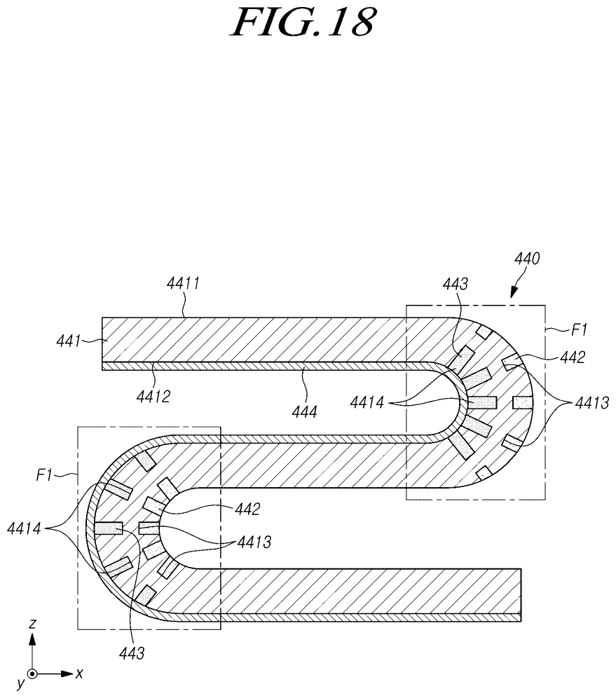

According to an embodiment, the glass layer 441 may include a plurality of patterns (e.g., the plurality of first patterns 4413 and the plurality of second patterns 4414 of FIG. 18) for reducing differences in touch feeling by area and/or providing flexibility at least in the first folding area F1 and the second folding area F2.

FIG. 18 is a view illustrating shape and arrangement configuration of a plurality of patterns according to a bending direction of the flexible display of FIG. 16 according to an example embodiment.

Referring to FIG. 18, a glass layer 441 (e.g., the glass layer 311 of FIG. 7) according to an embodiment may include a first surface 4411 and a second surface 4412 facing a direction opposite to the first surface 4411 and corresponding to a display panel 444.

According to an embodiment, the glass layer 441 may include a plurality of first patterns 4413 formed lower than the first surface 4411 at designated intervals on the first surface 4411. According to an embodiment, the glass layer 441 may include a plurality of second patterns 4414 formed lower than the second surface 4412 at designated intervals on the second surface 4412.

According to an embodiment, a first filling member 442 may be filling the plurality of first patterns 4413. According to an embodiment, a second filling member 443 may be filling the plurality of second patterns 4414.

According to an embodiment, the first filling member 442 may have substantially the same modulus, hardness, or molecular weight as the modulus, hardness, or molecular weight of the glass layer 441 to reduce a difference in touch feeling between the glass layer 441 and the filling member.

According to an embodiment, the first filling member 442 and the second filling member 443 may be designed to have different modulus, hardness, or molecular weight considering flexibility in the folding areas F1, F2. In an embodiment, the modulus, hardness, or molecular weight of the first filling member 442 may be provided to be greater than the modulus, hardness, or molecular weight of the second filling member 443.

For example, the first filling member 442 may be designed to have a modulus of 20 to 400 MPa, and the second filling member 443 may be designed to have a modulus of 0.005 to 10 MPa.

According to an embodiment, the glass layer 441 may help enhance flexibility by setting a depth of the plurality of first patterns 4413 disposed on the first surface 4411 to be shallower than a depth of the plurality of second patterns 4414 disposed on the second surface 4412 at least in the first folding area F1.

Further, the glass layer 441 may help enhance flexibility by setting a depth of the plurality of first patterns 4413 disposed on the first surface 4411 to be shallower than a depth of the plurality of second patterns 4414 disposed on the second surface 4412 at least in the second folding area F2.

For example, in one electronic device 400, flexibility may be enhanced by appropriately setting depths of the plurality of first patterns 4413 disposed on the first surface 4411 and the plurality of second patterns 4414 disposed on the second surface 4412 of the glass layer 441 according to methods of bending in different directions of the display panel 444.

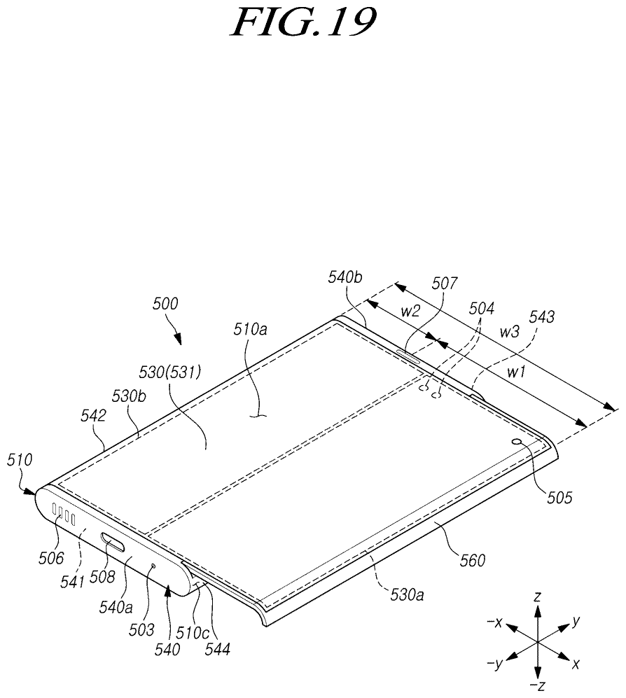

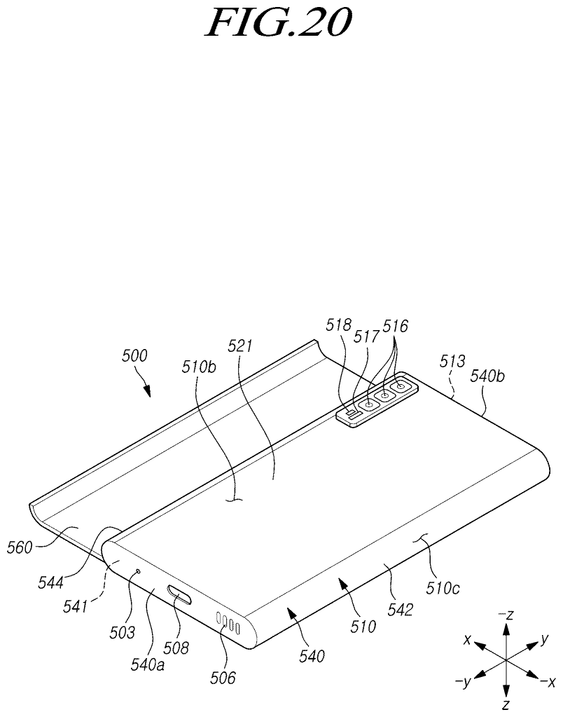

FIG. 19 is a view illustrating an extended state of an electronic device according to an example embodiment. FIG. 20 is a view illustrating a retracted state of an electronic device according to an example embodiment.

Referring to FIGS. 19 and 20, an electronic device 500 may include a housing 510 (e.g., first housing or base housing) and a slide structure 560 (e.g., second housing or slide housing) at least partially movably coupled from the housing 510 and supporting at least a portion of a flexible display 530.

According to an embodiment, the slide structure 560 may include a bendable member (not illustrated) (e.g., multi-joint hinge or multi-bar assembly) coupled at one end and supporting at least a portion of the flexible display 530. In case that the slide structure 560 performs a sliding operation in the housing 510, the bendable member may be at least partially retracted into an inner space of the housing 510 while supporting the flexible display 530.

According to an embodiment, the electronic device 500 may include a side member 540 including a front surface 510a facing a first direction (e.g., +z-axis direction), a rear surface 510b facing a second direction (e.g., −z-axis direction) opposite to the first direction, and a side surface 510c surrounding a space between the front surface 510a and the rear surface 510b and at least partially exposed to the outside.

According to an embodiment, the rear surface 510b may be formed through a rear cover 521 coupled to the housing 510. According to an embodiment, the rear cover 521 may be formed by polymer, coated or colored glass, ceramic, metal (e.g., aluminum, stainless steel, or magnesium), or a combination of at least two of the materials. In an embodiment, the rear cover 521 may be integrally formed with the housing 510.

According to an embodiment, at least a portion of the side surface 510c may be disposed to be exposed to the outside through the housing 510.

According to an embodiment, the side member 540 may include a first side surface 541 having a first length, a second side surface 542 extending from the first side surface 541 in a perpendicular direction to have a second length longer than the first length, a third side surface 543 extending from the second side surface 542 parallel to the first side surface 541 and having the first length, and a fourth side surface 544 extending from the third side surface 543 parallel to the second side surface 542 and having the second length.

According to an embodiment, the slide structure 560 may support the flexible display 530 and extend a display area of the flexible display 530 by sliding out from the second side surface 542 toward the fourth side surface 544 (e.g., +x-axis direction), or reduce the display area of the flexible display 530 by sliding in from the fourth side surface 544 toward the second side surface 542 (e.g., −x-axis direction).

According to an embodiment, the electronic device 500 may include a first side cover 540a and a second side cover 540b for covering the first side surface 541 and the third side surface 543.

According to an embodiment, the first side surface 541 and the third side surface 543 may be disposed not to be exposed to the outside through the first side cover 540a and the second side cover 540b.

According to an embodiment, the electronic device 500 may include a flexible display 530 disposed to receive support from the slide structure 560.

According to an embodiment, the flexible display 530 may include a first portion 530a (e.g., flat portion) supported by the slide structure 560 and a second portion 530b (e.g., bending portion or bendable portion) extending from the first portion 530a and at least partially supported through the bendable member.

According to an embodiment, at least a portion of the second portion 530b may be retracted into the inner space of the housing 510 and disposed not to be exposed to the outside in a retracted state of the electronic device 500 (e.g., a state in which at least a portion of the slide structure 560 is retracted into the housing 510). Further, at least a portion of the second portion 530b may be at least partially exposed to the outside to extend from the first portion 530a while receiving support from at least a portion of the bendable member in an extended state of the electronic device 500 (e.g., a state in which at least a portion of the slide structure 560 is extending from the housing 510). Therefore, the electronic device 500 may include a rollable type or slidable type electronic device in which a display area of the flexible display 530 changes according to movement of the slide structure 560 from the housing 510.

According to an embodiment, the slide structure 560 may be movably coupled in a sliding manner to be at least partially retracted or extending from the housing 510. For example, the flexible display 530 may be configured to have a display area corresponding to a first width w1 from the second side surface 542 to the fourth side surface 544 in a retracted state.

According to an embodiment, the flexible display 530 may be deformed to have a display area corresponding to a third width w3 greater than the first width w1 by at least a portion of the bendable member retracted inside the housing 510 being additionally moved to the outside of the electronic device to have a second width w2 in an extended state of the slide structure 560. Therefore, the display area of the flexible display 530 may be variable corresponding to a variable width of the electronic device according to a sliding operation of the slide structure 560.

According to an embodiment, the electronic device 500 may include at least one of an input device 503, sound output devices 506, 507, sensor modules 504, 517, camera modules 505, 516, a connector port 508, a key input device (not illustrated), or an indicator (not illustrated). In an embodiment, the electronic device 500 may omit at least one of the above-described components or may additionally include other components.

According to an embodiment, the input device 503 may include a microphone. In an embodiment, the input device 503 may include a plurality of microphones disposed to detect a direction of sound.

According to an embodiment, the sound output devices 506 and 507 may include speakers. The sound output devices 506, 507 may include an external speaker 506 and a receiver 507 for calls. In an embodiment, the sound output devices 506, 507 may include a speaker (e.g., piezo speaker) operated without a separate speaker hole.

According to an embodiment, the sensor modules 504 and 517 may generate an electrical signal or data value corresponding to an internal operating state or external environmental state of the electronic device 500. The sensor modules 504, 517 may include, e.g., a first sensor module 504 (e.g., proximity sensor or illuminance sensor) disposed on, directly or indirectly, the front and/or a second sensor module 517 (e.g., HRM sensor) disposed on, directly or indirectly, the rear.

According to an embodiment, the first sensor module 504 may be disposed below the flexible display 530 on the front surface 510a of the electronic device 500. The first sensor module 504 may further include at least one of a proximity sensor, an illuminance sensor, a time of flight (ToF) sensor, an ultrasonic sensor, a fingerprint recognition sensor, a gesture sensor, a gyro sensor, a barometric pressure sensor, a magnetic sensor, an acceleration sensor, a grip sensor, a color sensor, an infrared (IR) sensor, a biometric sensor, a temperature sensor, or a humidity sensor. According to an embodiment, the camera devices 505, 516 may include a first camera

device 505 disposed on, directly or indirectly, the front surface 510a of the electronic device 500 and a second camera device 516 disposed on, directly or indirectly, the rear surface 510b. According to an embodiment, the electronic device 500 may include a flash 518 positioned near the second camera device 516. According to an embodiment, the camera devices 505, 516 may include one or more lenses, an image sensor, and/or an image signal processor. According to an embodiment, the first camera device 505 may be disposed below the flexible display 530 and configured to capture a subject through a portion of an active area of the flexible display 530. According to an embodiment, the flash 518 may include, e.g., a light emitting diode or a xenon lamp. In an embodiment, two or more lenses (wide-angle and telephoto lenses) and image sensors may be disposed on, directly or indirectly, one surface of the electronic device 500.

According to an embodiment, the electronic device 500 may include at least one antenna (not illustrated). According to an embodiment, the at least one antenna may, e.g., communicate wirelessly with an external electronic device or wirelessly transmit/receive power necessary for charging. In an embodiment, the antenna may include a legacy antenna, an mmWave antenna, a near field communication (NFC) antenna, a wireless charging antenna, and/or a magnetic secure transmission (MST) antenna.

According to an embodiment, the flexible display 530 may include a glass layer 531 stacked on a display panel (e.g., the display panel 330 of FIG. 5).

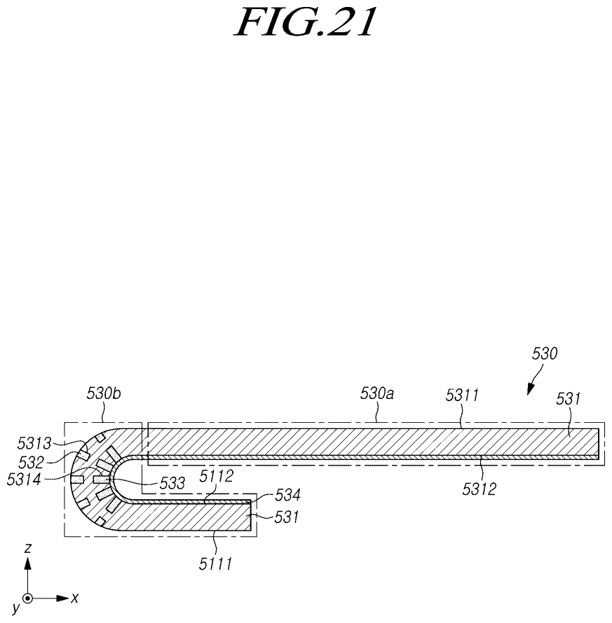

According to an embodiment, the glass layer 531 may help secure rigidity and flexibility of the flexible display 530 by including a plurality of patterns (e.g., the plurality of patterns 5313, 5314 of FIG. 21) formed in an area corresponding to the second portion 530b that is at least partially bendably deformed in case that the slide structure 560 performs a sliding operation in a designated direction.

FIG. 21 is a view illustrating shape and arrangement configuration of a plurality of patterns according to bending of a flexible display in a bendable area according to an example embodiment.

Referring to FIG. 21, a glass layer 531 (e.g., the glass layer 311 of FIG. 7) according to an embodiment may include a first surface 5311 and a second surface 5312 facing a direction opposite to the first surface 5311 and corresponding to a display panel 534.

According to an embodiment, the glass layer 531 may include a plurality of first patterns 5313 formed lower than the first surface 5311 at designated intervals on the first surface 5311. According to an embodiment, the glass layer 531 may include a plurality of second patterns 5314 formed lower than the second surface 5312 at designated intervals on the second surface 5312.

According to an embodiment, a first filling member 532 may be filling the plurality of first patterns 5313. According to an embodiment, a second filling member 533 may be filling the plurality of second patterns 5314.

According to an embodiment, the first filling member 532 may have substantially the same modulus, hardness, or molecular weight as the modulus, hardness, or molecular weight of the glass layer 531 to reduce a difference in touch feeling between the glass layer 531 and the filling member.

According to an embodiment, the first filling member 532 and the second filling member 533 may be designed to have different modulus, hardness, or molecular weight considering flexibility in an area corresponding to at least a portion of the second portion 530b of the flexible display 530. In an embodiment, the modulus, hardness, or molecular weight of the second filling member 533 may be provided to be less than the modulus, hardness, or molecular weight of the first filling member 532.

For example, the first filling member 532 may be designed to have a modulus of 20 to 400 MPa, and the second filling member 533 may be designed to have a modulus of 0.005 to 10 MPa.

According to an embodiment, the glass layer 531 may help enhance flexibility by setting a depth of the plurality of first patterns 5313 disposed on the first surface 5311 to be shallower than a depth of the plurality of second patterns 5314 disposed on the second surface 5312 in an area corresponding to at least a portion of the second portion 530b of the flexible display 530.

An electronic device 200 according to an example embodiment may include a first housing 210. The electronic device 200 may include a second housing 220 foldably connected, directly or indirectly, to the first housing 210 through at least a hinge module 240. The electronic device 200 may include a flexible display 300 supported by, directly or indirectly, the first housing 210 and the second housing 220. The flexible display 300 may include a glass layer 311 having a first surface 3111 and a second surface 3112 opposite to the first surface 3111, and including a plurality of first patterns 3113 recessed from the first surface 3111 and a plurality of second patterns 3114 recessed from the second surface 3112. The flexible display 300 may include a first filling member 312 filling the plurality of first patterns 3113. The flexible display 300 may include a second filling member 313 filling the plurality of second patterns 3114 and having a lower hardness than the first filling member 312.

According to an embodiment, a recessed depth d1 of the plurality of first patterns 3113 may be substantially the same as a recessed depth d2 of the plurality of second patterns 3114.

According to an embodiment, a recessed depth d1 of the plurality of first patterns 3113 may be shallower than a recessed depth d2 of the plurality of second patterns 3114.

According to an embodiment, the flexible display 300 may include a coating layer 314 stacked on the first surface 3111 of the glass layer 311 and hard-coated or anti-fingerprint coated.

According to an embodiment, a hardness of the first filling member 312 may be 20 to 400 MPa, and a hardness of the second filling member 313 may be 0.005 to 10 MPa.

According to an embodiment, a recessed depth d1 of the plurality of first patterns 3113 may be 20 μm or more.

According to an embodiment, the glass layer 311 may have its surface chemically strengthened by alkali ion exchange.

According to an embodiment, a pattern interval Ta of the plurality of first patterns 3113, a pattern interval Tb of the plurality of second patterns 3114, and a separation distance Tc between the plurality of first patterns 3113 and the plurality of second patterns 3114 may be 30 μm or more.

According to an embodiment, the flexible display 300 may include at least one planarization layer 3121, 3131 stacked on the first surface 3111 and/or the second surface 3112 of the glass layer 311.

According to an embodiment, the at least one planarization layer 3121, 3131 may include a first planarization layer 3121 stacked on the first surface 3111 and a second planarization layer 3131 stacked on the second surface 3112. The first planarization layer 3121 may be formed of the same material as the first filling member 312, and the second planarization layer 3131 may be formed of the same material as the second filling member 313.

According to an embodiment, a planarization layer 3121 stacked on the first surface 3111 may be formed with a thickness in a range of 10 to 30 μm.

According to an embodiment, the flexible display 300 may include a first flat portion 230a facing the first housing 210, a second flat portion 230b facing the second housing 220, and a bendable portion 230c connecting the first flat portion 230a and the second flat portion 230b, facing the hinge module 240 and capable of bending.

According to an embodiment, the plurality of first patterns 3113 and the plurality of second patterns 3114 may be disposed in an area corresponding to the bendable portion 230c of the flexible display 300.

According to an embodiment, flexibility of the area may be determined by shape, arrangement, and/or hardness of the plurality of patterns 3113, 3114.

According to an embodiment, the plurality of first patterns 3113 and the plurality of second patterns 3114 may be formed in a wave, stripe, or zigzag shape.

An electronic device 400, 500 according to an example embodiment may include at least one housing 410, 420, 430, 510. The electronic device 400, 500 may include a flexible display 440, 530 including a bending area F1, F2, 530b at least partially bendable through support of the at least one housing 410, 420, 430, 510. The flexible display 440, 530 may include a glass layer 441, 531 including a plurality of first patterns 4413, 5313 recessed from a first surface 4411, 5311 and a plurality of second patterns 4414, 5314 recessed from a second surface 4412, 5312 opposite to the first surface 4411, 5311. The flexible display 440, 530 may include a first filling member 442, 532 filling the plurality of first patterns 4413, 5313. The flexible display 440, 530 may include a second filling member 443, 533 filling the plurality of second patterns 4414, 5314 and having a lower hardness than the first filling member 442, 532.

According to an embodiment, the plurality of first patterns 4413, 5313 and the plurality of second patterns 4414, 5314 may be disposed in an area corresponding to the bending area F1, F2, 530b.

According to an embodiment, a recessed depth of the plurality of first patterns 4413, 5313 may be substantially the same as a recessed depth of the plurality of second patterns 4414, 5314.

According to an embodiment, a recessed depth of the plurality of first patterns 4413, 5313 may be shallower than a recessed depth of the plurality of second patterns 4414, 5314. A flexible display 300 including a flat portion 230a, 230b and a bendable portion 230c

according to an example embodiment may include a glass layer 311 including a plurality of first patterns 3113 recessed from a first surface 3111 and a plurality of second patterns 3114 recessed from a second surface 3112 opposite to the first surface 3111. The flexible display 300 may include a first filling member 312 filling the plurality of first patterns 3113. The flexible display 300 may include a second filling member 313 filling the plurality of second patterns 3114 and having a lower hardness than the first filling member 312. The plurality of first patterns 3113 and the plurality of second patterns 3114 may be positioned in an area of the glass layer 311 corresponding to the bendable portion 230c of the flexible display 300.

1. An electronic device comprising:
a first housing;
a second housing foldably connected to the first housing via a hinge module comprising a hinge; and
a flexible display supported by at least the first housing and/or the second housing,
wherein the flexible display includes:
a glass based layer having a first surface and a second surface opposite to the first surface, and including a plurality of first patterns recessed from the first surface and a plurality of second patterns recessed from the second surface;
a first filling member, comprising filler material, substantially filling in the plurality of first patterns; and
a second filling member, comprising filler material, substantially filling in the plurality of second patterns and having a hardness lower than a hardness of the first filling member.

2. The electronic device according to claim 1,
wherein a depression depth of the plurality of first patterns is less than a depression depth of the plurality of second patterns.

3. The electronic device according to claim 1,
wherein the flexible display includes a coating layer disposed on, directly or indirectly, the first surface of the glass based layer and coated with a hard coating and/or anti-finger coating.

4. The electronic device according to claim 1,
wherein a depression depth of the plurality of first patterns is at least 20 μm.

5. The electronic device according to claim 1,
wherein the glass based layer has a surface chemically strengthened by alkali ions exchanges.

6. The electronic device according to claim 1,
wherein a pattern pitch of the plurality of first patterns, a pattern pitch of the plurality of second patterns, and a distance between the plurality of first patterns and the plurality of second patterns is at least 30 μm.

7. The electronic device according to claim 1,
wherein the flexible display includes at least one planarization layer disposed, directly or indirectly, on the first surface and/or the second surface of the glass based layer.

8. The electronic device according to claim 7,
wherein the at least one planarization layer includes a first planarization layer disposed on the first surface and a second planarization layer disposed on the second surface,
wherein the first planarization layer and the first filling member comprise a same material, and
wherein the second planarization layer and the second filling member comprise a same material.

9. The electronic device according to claim 1,
wherein the flexible display includes a first flat part facing the first housing, a second flat part facing the second housing, and a bendable part that connects the first flat part and the second flat part and faces the hinge module and is bendable.

10. The electronic device according to claim 9,
wherein the plurality of first patterns and the plurality of second patterns are disposed in an area corresponding to the bendable part of the flexible display.

11. The electronic device according to claim 10,
wherein a flexibility of the area is based on a shape, arrangement, and/or hardness of the plurality of patterns.

12. The electronic device according to claim 1,
wherein the plurality of first patterns and the plurality of second patterns are formed in at least one of a wave, stripe, or zigzag shape.

13. An electronic device comprising:
at least one housing; and
a flexible display supported by the at least one housing, the flexible display including an at least partially bendable bending area;
a glass layer including a plurality of first patterns recessed from a first surface and a plurality of second patterns recessed from a second surface opposite to the first surface;
a first filling member, comprising filler material, filled into the plurality of first patterns; and
a second filling member, comprising filler material, filled into the plurality of second patterns and having a hardness lower than that of the first filling member.

14. The electronic device according to claim 13,
wherein the plurality of first patterns and the plurality of second patterns are disposed in a region corresponding to the bending area.

15. The electronic device according to claim 13,
wherein a depression depth of the plurality of first patterns is less than a depression depth of the plurality of second patterns.

16. The electronic device of claim 1, wherein the first and second filling members comprise elastic material.

17. The electronic device of claim 1, wherein the first and second filling members each comprise resin.

18. The electronic device of claim 1, wherein at least one of the first and second filling members comprises at least one of silicon, urethane, or acrylic.

19. The electronic device of claim 1, wherein the first filling member has a modulus of from 20 to 400 MPa, and the second filling member has a modulus of from 0.005 to 10 MPa.
